(19) United States
(12) Patent Application Publication
(10) Pub. No.: US 2026/0040552 A1
(43) Pub. Date: Feb. 5, 2026

(54) CURVED PLUG FOR PROTECTION OF BACKSIDE SOURCE FORMATION OF VERTICAL PLANAR MEMORY CELLS

(71) Applicant: Micron Technology, Inc., Boise, ID (US)

(72) Inventors: Masaaki Higuchi, Yokohama (JP); Yoshiaki Fukuzumi, Yokohama (JP); Marc Aoulaiche, Boise, ID (US); Matthew J. King, Boise, ID (US)

(21) Appl. No.: 19/272,478

(22) Filed: Jul. 17, 2025

Related U.S. Application Data
(60) Provisional application No. 63/677,720, filed on Jul. 31, 2024.

(51) Int. Cl. H10B 43/27; H10B 41/27; H10B 41/35; H10B 43/35

(52) U.S. Cl. CPC H10B 43/27; H10B 41/27; H10B 41/35; H10B 43/35

(57) ABSTRACT

Methods, systems, and devices for curved plug for protection of backside source formation of vertical planar memory cells are described. A plug structure within a memory system may reduce exposure of other portions of the memory system to a source material during a backside source formation process. For example, the plug may be formed between memory cell pillars and a substrate. The plug may protect the source material from entering via any spaces between memory cell pillars. Each memory cell pillar may include or be coupled with a bit line structure that is in contact with the plug via curved or otherwise rounded connections. During backside source formation, the diffused materials may etch the plug, and may not enter other areas of the memory system. The curved connections between the bit line structures and the plug may improve string current through the bit line structures, among other examples described herein.

### CROSS REFERENCE

The present application for patent claims priority to U.S. Patent Application No. 63/677,720 by Higuchi et al., entitled “CURVED PLUG FOR PROTECTION OF BACKSIDE SOURCE FORMATION OF VERTICAL PLANAR MEMORY CELLS,” filed Jul. 31, 2024, which is assigned to the assignee hereof, and which is expressly incorporated by reference in its entirety herein.

### TECHNICAL FIELD

The following relates to one or more systems for memory, including an apparatus including a curved plug for protection of backside source formation of vertical planar memory cells.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 shows an example of a system that supports formation of an apparatus including a curved plug for protection of backside source formation of vertical planar memory cells in accordance with examples as disclosed herein.

FIGS. 2A through 2I show examples of memory architectures that support formation of an apparatus including a curved plug for protection of backside source formation of vertical planar memory cells in accordance with examples as disclosed herein.

FIGS. 3A through 3E show examples of memory architectures that support formation of an apparatus including a curved plug for protection of backside source formation of vertical planar memory cells in accordance with examples as disclosed herein.

FIGS. 4A through 4C show examples of memory architectures that support formation of an apparatus including a curved plug for protection of backside source formation of vertical planar memory cells in accordance with examples as disclosed herein.

FIG. 5 shows an example of a memory architecture that supports formation of an apparatus including a curved plug for protection of backside source formation of vertical planar memory cells in accordance with examples as disclosed herein.

FIGS. 6A through 6F show examples of memory architectures that support formation of an apparatus including a curved plug for protection of backside source formation of vertical planar memory cells in accordance with examples as disclosed herein.

FIG. 7 shows an example of a memory architecture that supports formation of an apparatus including a curved plug for protection of backside source formation of vertical planar memory cells in accordance with examples as disclosed herein.

FIG. 8 shows a flowchart illustrating a method or methods that support formation of an apparatus including a curved plug for protection of backside source formation of vertical planar memory cells in accordance with examples as disclosed herein.

### DETAILED DESCRIPTION

Some memory systems (e.g., apparatuses) include vertical planar memory cells, in which planar cell transistors (e.g., NAND memory cells) may be connected within a trench-like structure, for example, to form a more scaled memory array than some other arrays in which a cylinder-like structure or some other structure may be used for memory cells. A backside source formation process may be used to form a source for one or more of the memory cells by flipping an apparatus over, removing a substrate, and depositing source materials from the back side (e.g., via oxide-nitride-oxide (ONO) etching and poly diffusion). In some vertical planar cell structures, such as trench-shaped structures, there may be some spaces between memory cell pillars. As such, the source material may enter, via the holes, other regions in the apparatus, which may reduce efficiency, reduce control of a voltage threshold of the cell, and reduce reliability overall, among other examples.

Techniques, systems, and devices described herein provide for a plug structure within an apparatus to reduce exposure of other portions of the apparatus to the source material during a backside source formation process. For example, the plug may be formed between memory cell pillars within the trench and a corresponding substrate. The plug structure described herein may include one or more curved or otherwise rounded (e.g., not sharp) corners or edges to reduce resistance and improve current flow through a memory channel. For example, the plug may be filled with a conductive material (e.g., polysilicon or some other material) to protect the source material from entering via any spaces between memory cell pillars. The plug may include a first rectangular portion that extends along and underneath the trench including multiple memory cell pillars (e.g., a rectangular prism of conductive material. The plug may include a second, rounded, portion on top of the first rectangular portion. The rounded portion may be U-shaped, double-U shaped, or some other curved shape and may connect the plug to one or more bit line structures that extend vertically within the apparatus. Each memory cell pillar may thereby include a respective bit line structure (e.g., channel of conductive material, string) that is in contact with the same plug of conductive material via curved connections. The curved connections may include bit line structures extending via rounded corners instead of sharp corners or edges to reduce a resistance and improve string current through the bit line structures (e.g., strings of memory cells). The improved string current may enhance access operations, improving performance and reliability of the apparatus (e.g., memory system), among other examples. During a backside source formation, the diffused source materials may etch a portion of the plug, but may not enter other areas of the apparatus.

In addition to applicability in apparatuses as described herein, techniques for formation of a curved plug for protection of backside source formation of vertical planar memory cells may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by reducing an amount of source material, among other materials, that is diffused into an apparatus, thereby improving reliability. Moreover, the curved corners and edges of the plug to protect against source diffusion as described herein may reduce resistance within a memory channel, improving throughput and efficiency, among other examples. The described techniques may thereby decrease processing or latency times, improve response times, or otherwise improve user experience, among other benefits.

In addition to applicability in apparatuses as described herein, techniques for formation of a curved plug for protection of backside source formation of vertical planar memory cells may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by reducing an amount of source material, among other materials, that is diffused into an apparatus, improving reliability of the apparatus, and eliminating or otherwise reducing production processes and complexity while maintaining efficiency, which may result in lowered production emissions, may extend the life of electronic devices and thereby reduce electronic waste, among other benefits.

Features of the disclosure are illustrated and described in the context of systems, apparatuses, devices, and circuits. Features of the disclosure are further illustrated and described in the context of memory architectures and flowcharts.

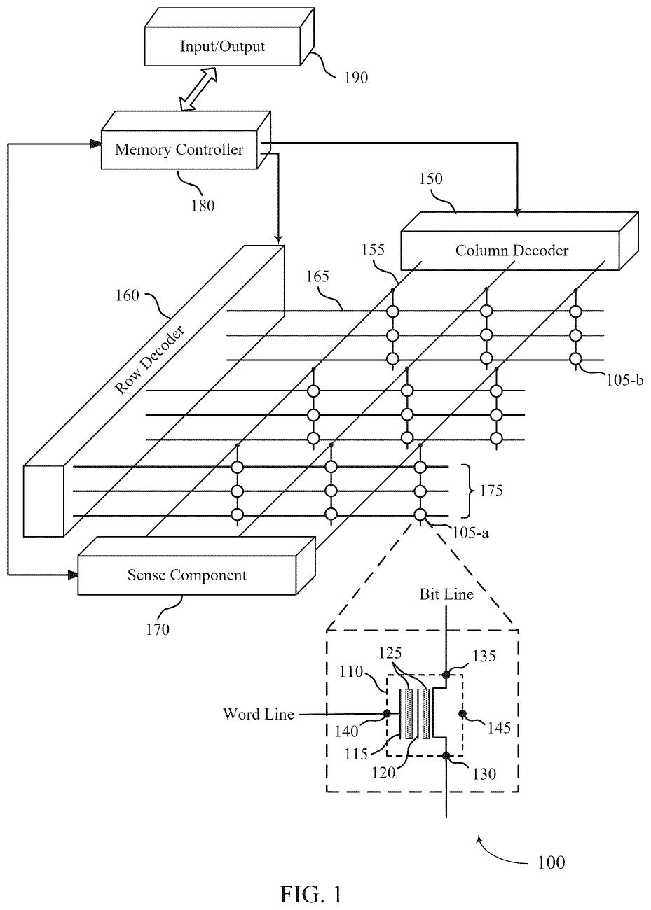

FIG. 1 shows an example of an apparatus 100 that supports curved plug for protection of backside source formation of vertical planar memory cells in accordance with examples as disclosed herein. FIG. 1 is an illustrative representation of various components and features of the apparatus 100. As such, the components and features of the apparatus 100 are shown to illustrate functional interrelationships, and not necessarily physical positions within the apparatus 100. Further, although some elements included in FIG. 1 are labeled with a numeric indicator, some other corresponding elements are not labeled, even though they are the same or would be understood to be similar, in an effort to increase visibility and clarity of the depicted features.

The apparatus 100 may include one or more memory cells 105, such as memory cell 105-a and memory cell 105-b. In some examples, a memory cell 105 may be a NAND memory cell, such as in the blow-up diagram of memory cell 105-a. Each memory cell 105 may be programmed to store a logic value representing one or more bits of information. In some examples, a single memory cell 105—such as a memory cell 105 configured as a single-level cell (SLC)—may be programmed to one of two supported states and thus may store one bit of information at a time (e.g., a logic 0 or a logic 1). In some other examples, a single memory cell 105—such a memory cell 105 configured as a multi-level cell (MLC), a tri-level cell (TLC), a quad-level cell (QLC), or other type of multiple-level memory cell 105—may be programmed to one state of more than two supported states and thus may store more than one bit of information at a time. In some cases, a multiple-level memory cell 105 (e.g., an MLC memory cell, a TLC memory cell, a QLC memory cell) may be physically different than an SLC cell. For example, a multiple-level memory cell 105 may use a different cell geometry or may be fabricated using different materials. In some examples, a multiple-level memory cell 105 may be physically the same or similar to an SLC cell, and other circuitry in a memory block (e.g., a controller, sense amplifiers, drivers) may be configured to operate (e.g., read and program) the memory cell as an SLC cell, or as an MLC cell, or as a TLC cell, etc.

In some NAND memory arrays, each memory cell 105 may be illustrated as a transistor that includes a charge trapping structure (e.g., a floating gate, a replacement gate, a dielectric material) for storing an amount of charge representative of a logic value. For example, the blow-up in FIG. 1 illustrates a NAND memory cell 105-a that includes a transistor 110 (e.g., a metal-oxide-semiconductor (MOS) transistor) that may be used to store a logic value. The transistor 110 may include a control gate 115 and a charge trapping structure 120 (e.g., a floating gate, a replacement gate), where the charge trapping structure 120 may, in some examples, be between two portions of dielectric material 125. The transistor 110 also may include a first node 130 (e.g., a source or drain) and a second node 135 (e.g., a drain or source). A logic value may be stored in transistor 110 by storing (e.g., writing) a quantity of electrons (e.g., an amount of charge) on the charge trapping structure 120. An amount of charge to be stored on the charge trapping structure 120 may depend on the logic value to be stored. The charge stored on the charge trapping structure 120 may affect the threshold voltage of the transistor 110, thereby affecting the amount of current that flows through the transistor 110 when the transistor 110 is activated (e.g., when a voltage is applied to the control gate 115, when the memory cell 105-a is read). In some examples, the charge trapping structure 120 may be an example of a floating gate or a replacement gate that may be part of a 2D NAND structure. For example, a 2D NAND array may include multiple control gates 115 and charge trapping structures 120 arranged around a single channel (e.g., a horizontal channel, a vertical channel, a columnar channel, a pillar channel).

A logic value stored in the transistor 110 may be sensed (e.g., as part of a read operation) by applying a voltage to the control gate 115 (e.g., to control node 140, via a word line 165) to activate the transistor 110 and measuring (e.g., detecting, sensing) an amount of current that flows through the first node 130 or the second node 135 (e.g., via a bit line 155). For example, a sense component 170 may determine whether an SLC memory cell 105 stores a logic 0 or a logic 1 in a binary manner (e.g., based on a presence or absence of a current through the memory cell 105 when a read voltage is applied to the control gate 115, based on whether the current is above or below a threshold current). For a multiple-level memory cell 105, a sense component 170 may determine a logic value stored in the memory cell 105 based on various intermediate threshold levels of current when a read voltage is applied to the control gate 115, or by applying different read voltages to the control gate and evaluating different resulting levels of current through the transistor 110, or various combinations thereof. In one example of a multiple-level architecture, a sense component 170 may determine the logic value of a TLC memory cell 105 based on eight different levels of current, or ranges of current, that define the eight potential logic values that could be stored by the TLC memory cell 105.

An SLC memory cell 105 may be written by applying one of two voltages (e.g., a voltage above a threshold or a voltage below a threshold) to the memory cell 105 to store, or not store, an electric charge on the charge trapping structure 120 and thereby cause the memory cell 105 to store one of two possible logic values. For example, when a first voltage is applied to the control node 140 (e.g., via a word line 165) relative to a bulk node 145 (e.g., a body node) for the transistor 110 (e.g., when the control node 140 is at a higher voltage than the bulk), electrons may tunnel into the charge trapping structure 120. Injection of electrons into the charge trapping structure 120 may be referred to as programming the memory cell 105 and may occur as part of a write operation. A programmed memory cell may, in some cases, be considered as storing a logic 0. When a second voltage is applied to the control node 140 (e.g., via the word line 165) relative to the bulk node 145 for the transistor 110 (e.g., when the control node 140 is at a lower voltage than the bulk node 145), electrons may leave the charge trapping structure 120. Removal of electrons from the charge trapping structure 120 may be referred to as erasing the memory cell 105 and may occur as part of an erase operation. An erased memory cell may, in some cases, be considered as storing a logic 1. In some cases, memory cells 105 may be programmed at a page level of granularity due to memory cells 105 of a page sharing a common word line 165, and memory cells 105 may be erased at a block level of granularity due to memory cells 105 of a block sharing commonly biased bulk nodes 145.

In contrast to writing an SLC memory cell 105, writing a multiple-level (e.g., MLC, TLC, or QLC) memory cell 105 may involve applying different voltages to the memory cell 105 (e.g., to the control node 140 or bulk node 145 thereof) at a finer level of granularity to more finely control the amount of charge stored on the charge trapping structure 120, thereby enabling a larger set of logic values to be represented. Thus, multiple-level memory cells 105 may provide greater density of storage relative to SLC memory cells 105 but may, in some cases, involve narrower read or write margins or greater complexities for supporting circuitry.

A charge-trapping NAND memory cell 105 may operate similarly to a floating-gate NAND memory cell 105 but, instead of or in addition to storing a charge on a charge trapping structure 120, a charge-trapping NAND memory cell 105 may store a charge representing a logic state in a dielectric material between the control gate 115 and a channel (e.g., a channel between a first node 130 and a second node 135). Thus, a charge-trapping NAND memory cell 105 may include a charge trapping structure 120, or may implement charge trapping functionality in one or more portions of dielectric material 125, among other configurations.

In some examples, each page of memory cells 105 may be connected to a corresponding word line 165, and each column of memory cells 105 may be connected to a corresponding bit line 155 (e.g., digit line). Thus, one memory cell 105 may be located at the intersection of a word line 165 and a bit line 155. This intersection may be referred to as an address of a memory cell 105. In some cases, word lines 165 and bit lines 155 may be substantially perpendicular to one another, and may be generically referred to as access lines or select lines.

In some cases, an apparatus 100 may include a three-dimensional (3D) memory array, where multiple two-dimensional (2D) memory arrays may be formed on top of one another. In some examples, such an arrangement may increase the quantity of memory cells 105 that may be fabricated on a single die or substrate as compared with 1D arrays, which, in turn, may reduce production costs, or increase the performance of the memory array, or both. In the example of FIG. 1, apparatus 100 includes multiple levels (e.g., decks, layers, planes, tiers) of memory cells 105. The levels may, in some examples, be separated by an electrically insulating material. Each level may be aligned or positioned so that memory cells 105 may be aligned (e.g., exactly aligned, overlapping, or approximately aligned) with one another across each level, forming a memory cell stack 175. In some cases, memory cells aligned along a memory cell stack 175 may be referred to as a string of memory cells 105.

Accessing memory cells 105 may be controlled through a row decoder 160 and a column decoder 150. For example, the row decoder 160 may receive a row address from the memory controller 180 and activate an appropriate word line 165 based on the received row address. Similarly, the column decoder 150 may receive a column address from the memory controller 180 and activate an appropriate bit line 155. Thus, by activating one word line 165 and one bit line 155, one memory cell 105 may be accessed. As part of such accessing, a memory cell 105 may be read (e.g., sensed) by sense component 170. For example, the sense component 170 may be configured to determine the stored logic value of a memory cell 105 based on a signal generated by accessing the memory cell 105. The signal may include a current, a voltage, or both a current and a voltage on the bit line 155 for the memory cell 105 and may depend on the logic value stored by the memory cell 105. The sense component 170 may include various circuitry (e.g., transistors, amplifiers) configured to detect and amplify a signal (e.g., a current or voltage) on a bit line 155. The logic value of memory cell 105 as detected by the sense component 170 may be output via input/output component 190. In some cases, a sense component 170 may be a part of a column decoder 150 or a row decoder 160, or a sense component 170 may otherwise be connected to or in electronic communication with a column decoder 150 or a row decoder 160.

A memory cell 105 may be programmed or written by activating the relevant word line 165 and bit line 155 to enable a logic value (e.g., representing one or more bits of information) to be stored in the memory cell 105. A column decoder 150 or a row decoder 160 may accept data (e.g., from the input/output component 190) to be written to the memory cells 105. In the case of NAND memory, a memory cell 105 may be written by storing electrons in a charge trapping structure or an insulating layer.

A memory controller 180 may control the operation (e.g., read, write, re-write, refresh) of memory cells 105 through the various components (e.g., row decoder 160, column decoder 150, sense component 170). In some cases, one or more of a row decoder 160, a column decoder 150, and a sense component 170 may be co-located with a memory controller 180. A memory controller 180 may generate row and column address signals in order to activate a desired word line 165 and bit line 155. In some examples, a memory controller 180 may generate and control various voltages or currents used during the operation of apparatus 100.

Some memory systems (e.g., apparatuses, such as the apparatus 100) include vertical planar memory cells, in which planar cell transistors may be connected within a trench-like structure to form a more scaled memory array than some other arrays in which a cylinder-like structure or some other structure may be used for memory cells. The planar cell transistors may be connected in a vertical direction (e.g., height, stacked). Scaling a width of the cell (e.g., AA width) and a cell-to-cell distance (e.g., a pitch, or AA-to-AA distance) may be a cell size scaling vector.

A backside source formation process may be used to form a source for one or more of the memory cells by flipping an apparatus 100 over, removing a substrate, and depositing source materials from the back side (e.g., via oxide-nitride-oxide (ONO) etching and poly diffusion). In some vertical planar cell structures, such as trench-shaped structures, there may be some spaces between memory cell pillars. As such, the source material may enter, via the holes, other regions in the apparatus 100, which may reduce efficiency, reduce control of a voltage threshold of the cell, and reduce reliability overall, among other examples. For example, when creating a source gate selector (SGS) using a backside contact that attached the wafer (e.g., substrate) to the vertical planar cell, a chemical solution that etches the insulator film may enter between split memory channels (e.g., doped hollow channels), which may increase difficulty in adjusting a position of an n+ layer. Additionally, or alternatively, the chemical liquid that gets inside the cell structure may damage the cell. In some examples, an n+ poly-silicon may enter the cell side and reduce a threshold voltage of the cell.

As described herein, the apparatus 100 may be formed with a rounded plug structure to reduce exposure of other portions of the apparatus 100 to the source material during a backside source formation process. That is, the SGS structure described herein may provide for a realization of vertical planar cell structures to achieve cell size reduction. The SGS structure described herein may reduce over wet etching during oxide-nitride-oxide films in a memory channel. For example, the plug may be formed between memory cell pillars within the trench and a corresponding substrate. The plug structure described herein may include one or more curved or otherwise rounded (e.g., not sharp) corners or edges to reduce resistance and improve current flow through a memory channel. For example, the plug may be filled with a conductive material (e.g., polysilicon or some other material) to protect the source material from entering via any spaces between memory cell pillars. The plug may include a first rectangular portion that extends along and underneath the trench including multiple memory cell pillars (e.g., a rectangular prism of conductive material). The plug may include a second, rounded, portion on top of the first rectangular portion. The rounded portion may be U-shaped, double-U shaped, or some other curved shape and may connect the plug to one or more bit line structures that extend vertically within the apparatus 100 between the plug and one or more bit lines 155 (e.g., digit lines). Each memory cell pillar (e.g., string) may thereby include a respective bit line structure (e.g., channel of conductive material) that is in contact with the same plug of conductive material via curved connections. The curved connections may include bit line structures extending via rounded corners instead of sharp corners or edges to reduce a resistance and improve string current through the bit line structures. The improved string current may enhance access operations, improving performance and reliability of the apparatus, among other examples. During a backside source formation, the diffused source materials may etch a portion of the plug, but may not enter other areas of the apparatus.

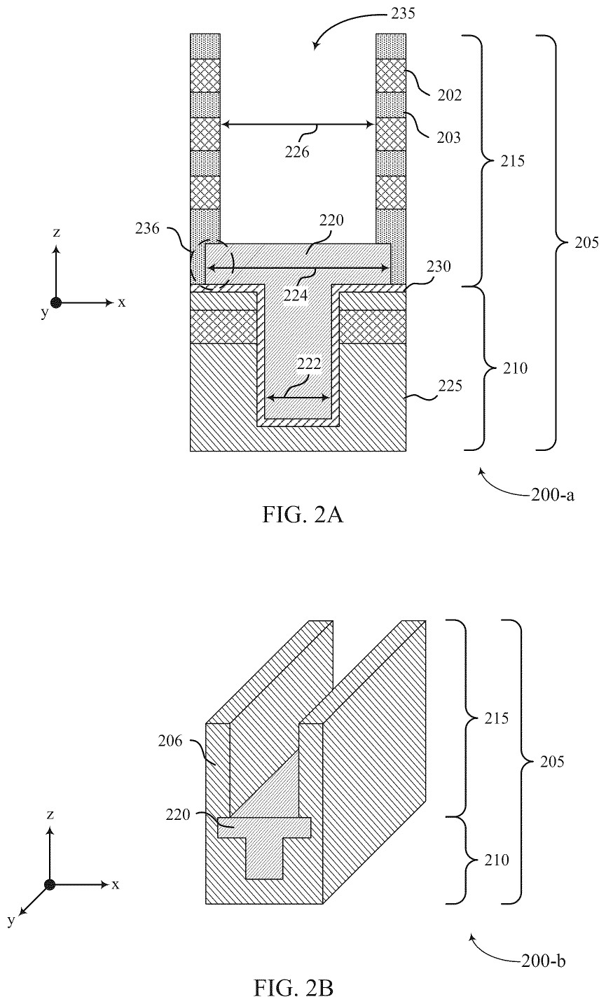

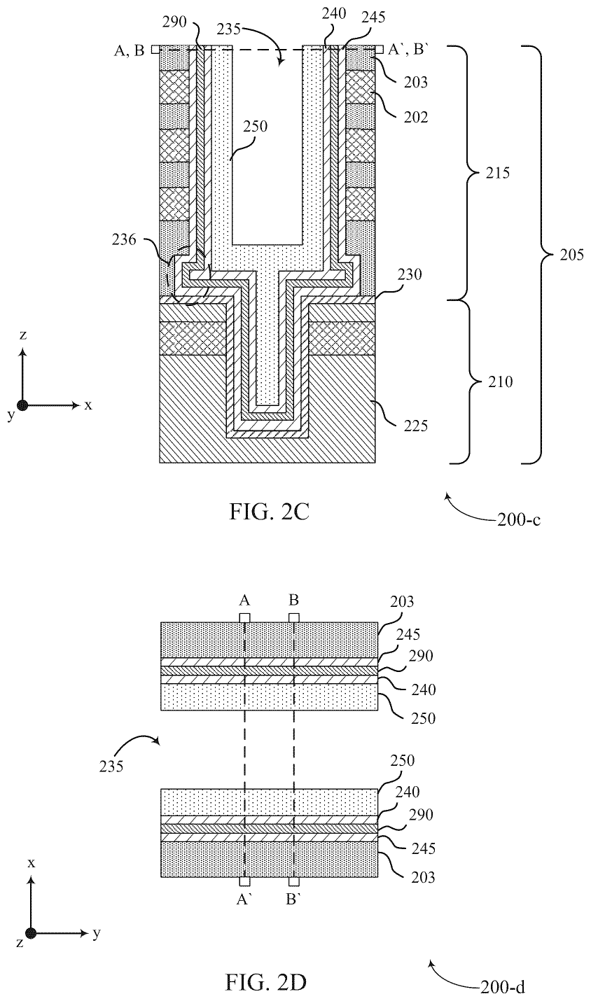

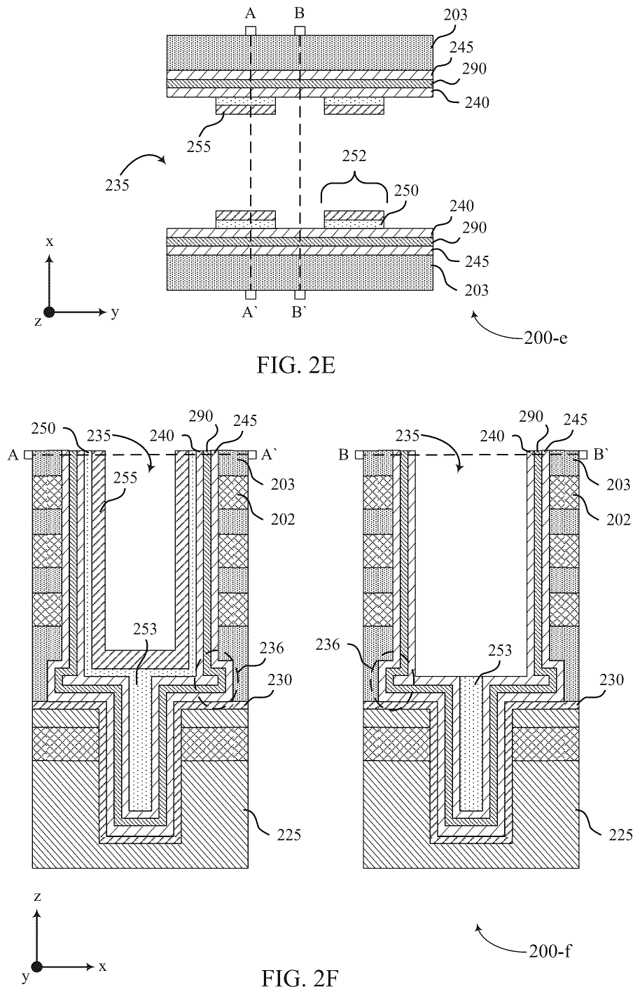

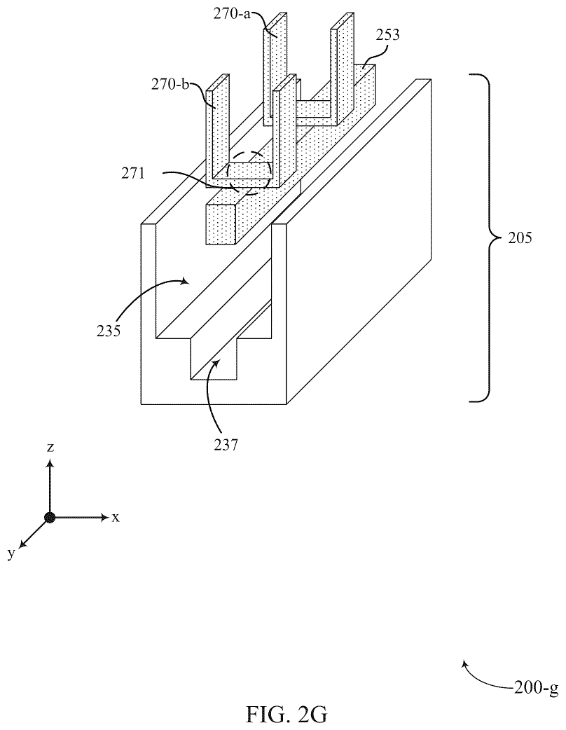

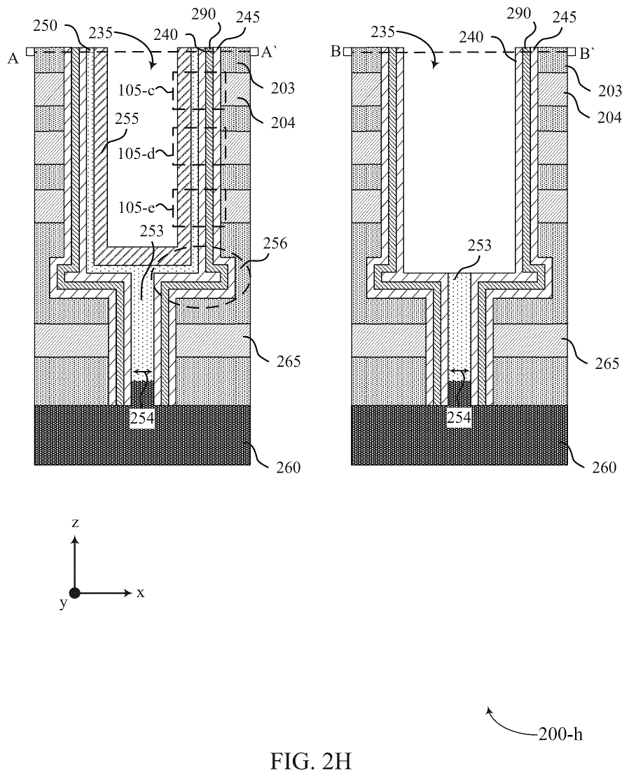

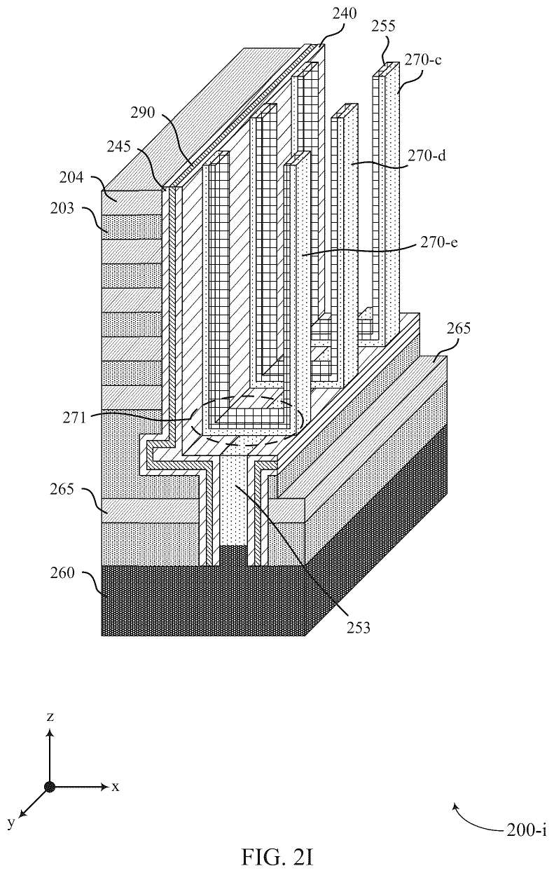

FIGS. 2A through 2I show examples of memory architectures 200 that support formation of a curved plug for protection of backside source formation of vertical planar memory cells in accordance with examples as disclosed herein. The memory architecture 200 may be an example of a portion of an apparatus, such as an apparatus 100. FIGS. 2A through 2I show various views (e.g., diagonal or trimetric views, planar views, other views) of a memory architecture 200, which may be an example of a memory architecture implemented by an apparatus 100, as described with reference to FIG. 1. The memory architectures 200 may illustrate operations associated with forming an apparatus including memory cells across one or more levels of the apparatus that are connected with respective bit lines. Performing the processing steps may consolidate processing steps otherwise associated with forming a memory architecture. For example, the processing steps may support reduced diffusion of a source material to unnecessary regions of an apparatus, among other advantages.

For illustrative purposes, aspects of the memory architecture may be described with reference to an x-direction, a y-direction, and a z-direction of the illustrated coordinate systems. For example, memory architectures 200-b, 200-g, and 200-i illustrate the memory architecture from trimetric views, where a substrate of the memory architecture may be associated with an xy-plane, and where the memory architecture extends a distance along the z-direction. Additionally, the memory architectures 200-a, 200-c, 200-d, 200-e, 200-f, and 200-h, may illustrate the memory architecture with a cross-sectional and/or planar view, such that a portion of the memory architecture may be removed from the trimetric view to illustrate a cross-section of the memory architecture in the xz-plane, the xy-plane, or both. Although the memory architectures 200 illustrate examples of relative dimensions and quantities of various features, aspects of the memory architectures 200 may be implemented with other relative dimensions or quantities of such features in accordance with examples as disclosed herein. In the following description of the processing steps, some methods, techniques, processes, and operations may be performed in different orders or at different times. Further, some operations may be left out of the processing steps, or other operations may be added to the processing steps. Although described as singular processing steps, it is to be understood that each processing step may include one or more multiple processing operations, including, but not limited to, formations, depositions, etches, removals, exhumes, other processing steps, or the like.

Processing steps illustrated in and described with reference to FIGS. 2A through 2I may be performed by a manufacturing system, such as a semiconductor fabrication system configured to perform additive operations such as deposition, formation, bonding, and/or coupling, subtractive operations such as etching, trenching, planarizing, and/or polishing, and supporting operations such as masking, patterning, photolithography, and/or aligning, among other operations that support the described techniques. In some examples, operations performed by such a manufacturing system may be supported by one or more controllers, such as one or more processors or processing circuitry, or its components as described herein.

FIG. 2A illustrates an example of a memory architecture 200-a after a first processing step associated with forming a stack of materials 205 and a sacrificial plug 220. For example, forming the stack of materials 205 may include depositing alternating (e.g., or at least partially alternating) layers of an oxide material 203 and a sacrificial material 202 above a substrate (e.g., a plane or sheet in the xy-plane on which subsequent memory materials may be formed. The substrate may be associated with complementary metal-oxide semiconductor (CMOS) circuitry. In some such examples, depositing the alternating layers may include depositing a layer of the oxide material 203, then depositing a layer of the sacrificial material 202 above the layer of the oxide material 203. Accordingly, the sacrificial material 202 and the oxide material 203 may be similarly deposited to form alternating layers, where the height of the stack of materials 205 may be based on the quantity and height of each of the alternating layers. In some implementations, the oxide material 203 may be a dielectric material, such as silicon oxide, silicon oxycarbide, silicon oxynitride, or silicon nitride. In some implementations, the sacrificial material 202 may be a variation of nitride.

In some examples, the stack of materials 205 may be formed in two or more formation processes. For example, the first level 210 may be formed first, and the second level 215 may be formed after formation of the first level 210. Forming the first level 210 may include depositing one or more layers of an oxide material 225 and one or more layers of the sacrificial material 202. The oxide material 225 may be the same as or different from the oxide material 203 in the second level 215. In some examples, after the first level 210 is formed, the first level 210 may be etched to form a first cavity (not pictured in FIG. 2A) having a first width 222. The first cavity may pass through the first level 210 of the stack of materials 205 in a first direction (e.g., vertical, the z-direction) and a second direction (e.g., horizontal, the y-direction), having a width 222 in a third direction (e.g., the x-direction). The first cavity may not extend fully through the first level 210, such that a portion of oxide material 225 may remain between the first cavity and a substrate, in some examples. The first cavity may be filled with a sacrificial material 230, which may be an oxide material, such as the oxide material 203, or some other material. The second level 215 may then be formed on top of the first level 210 including the cavity filled with the sacrificial material 230. In some examples, as illustrated in FIG. 2A, the sacrificial material 230 may form a liner between the first level 210 and a first layer of oxide material 203 in the second level 215.

After forming the second level 215 of the stack of materials 205, one or more other cavities may be formed. For example, a second cavity 235 may be formed in the second level 215 of the stack of materials 205. The second cavity 235 may be above the first cavity relative to the substrate. The second cavity 235 may pass through the second level 215 of the stack of materials 205 in the first direction (e.g., the z-direction) and the second direction (e.g., the y-direction). The first cavity and the second cavity 235 may be formed via respective etch processes in which materials are removed from the stack of materials 205 to form the cavities. The first cavity may be formed with a first width 222 and the second cavity 235 may be formed with a second width 226, where the second width 226 is greater than the first width 222.

In some examples, a recess 236 may be formed within the stack of materials 205 between the first cavity and the second cavity 235. For example, a portion of a first layer of oxide material 203 in the second level 215 of the stack of materials 205 may be etched to form a recess 236 (e.g., on each side of the stack) that expands a width of the second cavity 235 from the second width 226 to a third width 224 that is greater than the first width 222 and the second width 226.

After forming the stack of materials 205 and the various cavities, a sacrificial plug 220 may be formed within the first cavity and the recess 236. For example, a sacrificial plug material may be deposited within the first cavity and the recess 236 to form the sacrificial plug 220. In some examples, the formation of the sacrificial plug 220 may form the recess 236 (e.g., the sacrificial plug material may etch back or recede a portion of the oxide material 203). Additionally, or alternatively, the sacrificial plug 220 may be formed within the first cavity before formation of the second level 215, and the second level 215 may be formed on top of the sacrificial plug 220. The sacrificial plug 220 may be a T-shaped plug, or some other shape having the first width 222 in the first level 210 of the stack and the third width 224 in the second level 215 of the stack.

FIG. 2B illustrates an example of a memory architecture 200-b after the first processing step associated with forming the sacrificial plug 220 within the stack of materials 205. For example, the memory architecture 200-b illustrates a trimetric view (e.g., a diagonal view) of the stack of materials 205 illustrated in FIG. 2A. For clarity, some features of the stack of materials 205 are not illustrated in FIG. 2B. For example, the material 206 may be a simplified representation of the alternating layers of materials, including the oxide material 203 and the sacrificial material 202, as described with reference to FIG. 2A.

As illustrated in FIG. 2B, after the sacrificial plug 220 is formed, the stack of materials 205 may represent a trench-shape, where the sacrificial plug 220 may be a T-shape that extends horizontally (e.g., in the y-direction) through the stack of materials 205 and further extends vertically (e.g., in the z-direction) in a portion of the first level 210 and a portion of the second level 215.

FIG. 2C illustrates an example of a memory architecture 200-c after a second processing step associated with forming various layers of materials within the stack of materials 205. For example, the sacrificial plug 220 may be removed (e.g., etched, exhumed) from the stack of materials 205, and one or more layers of materials may be deposited or formed within the first cavity, the recess 236, and the second cavity 235 after the sacrificial plug 220 is removed. The layers of materials may include, for example, a first protective liner 245, a storage material 290, and a second protective liner 240. The materials may be deposited and subsequently etched back to form liners that extend along sidewalls of the stack of materials 205. For example, the first protective liner 245 may extend along sidewalls of the stack of materials 205 within the first cavity, within the recess 236, and within the second cavity 235. The storage material 290 may extend along the first protective liner 245 and between the first protective liner 245 and the second protective liner 240. In some examples, the second protective liner 240 may be deposited and subsequently etched such that a shape of the second protective liner 240 may generally be a U-shape within the second level 215. That is, the second protective liner 240 may include, in some examples, fewer or no curves within the recess 236 than the first protective liner 245 and/or the storage material 290.

After the first protective liner 245, the storage material 290, and the second protective liner 240 are formed, a conductive material 250 may be formed (e.g., deposited) over the second protective liner 240 within a remainder of the first cavity and a portion of the second cavity 235. The conductive material 250 may be associated with one or more bit line structures of the apparatus. A size of the second cavity 235 after these depositions of materials may be reduced as compared with the size of the second cavity 235 in FIG. 2A. The conductive material 250 may thereby fill the first cavity, such that the first level 210 is filled with materials. The conductive material 250 may, in some examples, be formed in the shape of a football field goal post, or a rectangular U-shape connected to a vertical post.

FIG. 2D illustrates an example of a memory architecture 200-d after the second processing step described with reference to FIG. 2C. For example, FIG. 2D illustrates the stack of materials 205 from a birds-eye view (e.g., in the xy-plane). The memory architecture 200-d shown in FIG. 2D illustrates a cross-sectional view of the memory architecture 200-c shown in FIG. 2C, as cut across the A-A′ and B-B′ cross-sectional lines.

As shown in FIG. 2D, after the various materials are formed, a top layer of the apparatus may include two sets of material segments. Each set of material segments including the oxide material 203, the first protective liner 245, the storage material 290, the second protective liner 240, and the conductive material 250. The two sets of materials may be sandwiched together with a space (e.g., the second cavity 235) in between the two sets of materials.

Although not pictured in FIG. 2D, it is to be understood that the second cavity 235 may extend some distance into the page in the z-direction, and there may be more conductive material 250 after the distance, as illustrated in FIG. 2C.

FIG. 2E illustrates an example of a memory architecture 200-e after a third processing step associated with etching back the conductive material 250. The memory architecture 200-e illustrates a birds-eye view of the stack of materials 205 (e.g., in the xy-plane). For example, the memory architecture 200-e illustrates a cross-sectional view of the memory architectures 200-f shown in FIG. 2F, as cut across the A-A′ and B-B′ cross-sectional lines.

The third processing step may include, for example, depositing a channel oxide material 255 within the second cavity 235. The channel oxide material 255 may be formed on top of the conductive material 250 and may be formed with a threshold thickness or may be etched back, such that the channel oxide material 255 has a relatively constant thickness within the second cavity 235. In some examples, the formation of the channel oxide material 255 may reduce a thickness of the conductive material 250 within the second cavity 235, as illustrated in FIG. 2E.

The third processing step may further include etching the conductive material 250 and the channel oxide material 255. The etching may be performed using a mask, which may cover some portions of the stack of materials and expose other portions. The conductive material 250 and the channel oxide material 255 within the exposed portions may be removed (e.g., etched, exhumed, or the like). There may be remaining segments 252 of conductive material 250 within the second cavity 235 (e.g., a trench). The conductive material 250 may be etched such that each segment 252 of conductive material is separated from (e.g., not in direct physical contact with) any other segment 252 of the conductive material within the second level 215 of the stack. The channel oxide material 255 may be etched to a similar or the same shape as the conductive material 250. In some examples, the channel oxide material 255 may be formed on top of the conductive material 250 after the etching. Additionally, or alternatively, the channel oxide material 255 may be formed prior to the etching.

FIG. 2F illustrates an example of a memory architecture 200-f after the third processing step described with reference to FIG. 2E. The memory architecture 200-f represents an example of the memory architecture 200-e illustrated in FIG. 2E, but from a horizontal view (e.g., in the xz-plane). The memory architecture 200-f may represent cross sectional views of the memory architecture 200-e when cut across the A-A′ and B-B′ cross-sectional lines.

When cut across the A-A′ cross-sectional line, the memory architecture 200-f may include each of the first protective liner 245, the storage material 290, and the second protective liner 240 extending along sidewalls of the stack of materials 205. The memory architecture 200-f may further include the conductive material 250 within the first level 210 and the second level 215 (e.g., within the second cavity 235). The channel oxide material 255 may further be included within the A-A′ cross-sectional view as a U-shape on top of the conductive material 250 in the second cavity 235. The conductive material 250 within the first level 210 of the stack may be referred to as a plug 253 herein. For example, the plug 253 may include all of the conductive material 250 that extends continuously in the y direction through the stack of materials 205 (e.g., to form a trench-shape). The conductive material 250 that extends from the plug 253 vertically within the second level 215 may be referred to as the segments 252. Thus, when the memory architecture 200-e illustrated in FIG. 2E is cut across the areas that include the segments 252, the conductive material 250 and the channel oxide material 255 are present within the second cavity 235.

However, when cut across the B-B′ cross-sectional line, the view of the memory architecture 200-f may not include the channel oxide material 255 and may not include the conductive material 250 along the sidewalls of the second cavity 235. For example, because of the etching performed in the third processing step, the conductive material 250 may be formed in U-shaped segments (e.g., rectangular U-shaped segments) within the second cavity 235, where the segments 252 extend from the plug 253 horizontally (e.g., in the x-direction) to a sidewall of the second cavity 235 (e.g., to the second protective liner 240), and then vertically (e.g., in the z-direction) along the sidewall of the second cavity 235 (e.g., along the second protective liner 240). The segments 252 may not, however, extend continuously in the x-direction. Instead, the segments 252 may have a threshold thickness in the x-direction due to the etching. In between the segments 252 may be some other insulating material or an absence of material (e.g., air), at least for part of the manufacturing process. As such, the cross-sectional view of the B-B′ cross-section may not include any conductive material 250 extending from the plug 253 and may instead include the plug 253 that terminates at the second cavity 235.

FIG. 2G illustrates an example of a memory architecture 200-g in accordance with an abstracted trimetric view after the third processing step described herein. The memory architecture 200-g is abstracted to improve clarity and highlight the shape of the plug 253 and corresponding bit line structures 270 (e.g., bit line structures 270-a and 270-b), each of which may include the conductive material 250 described with reference to FIGS. 2A through 2F. The plug 253 and the bit line structures 270 may be removed from the stack of materials 205 for illustration purposes only, and it is to be understood that the plug 253 may be within the first cavity 237 and the bit line structures 270 may be within the second cavity 235, as described and illustrated with reference to FIGS. 2A through 2F.

As illustrated in FIG. 2G, the plug 253 may be a rectangular or cubic shape that extends in the y-direction (e.g., horizontally) within a trench formed by the first cavity 237 in the first level of the stack of materials 205. The plug 253 may have a first thickness in the x-direction and a second thickness in the z-direction, where the first and second thicknesses may be the same or different. The plug 253 may provide a continuous and solid base connection point for each of the bit line structures 270, which may protect against a source material being diffused throughout the memory architecture 200-g. The bit line structures 270 may be in direct physical contact with the plug 253 at a base contact region 271 and may otherwise be separated from one another. For example, the bit line structure 270-a may not be in direct physical contact with the bit line structure 270-b. There may be an absence of material or some insulating material between the two bit line structures 270-a and 270-b in the y-direction. The bit line structures 270 may each extend horizontally in the x-direction from the base contact region 271 to sidewalls of the second cavity 235 and may extend vertically in the z-direction within the stack of materials 205 and along sidewalls of the second cavity 235. The bit line structures 270 may be configured as bit lines that may active or select one or more memory cells within the stack (e.g., memory cell pillars). Additionally, or alternatively, the bit line structures 270 may represent examples of conductive lines (e.g., strings) of memory cells 105 coupled between two selectors. For example, the bit line structures 270 may represent a conductive channel between memory cells 105. A bit line may be coupled with a top portion of the bit line structures 270 via a selector, such as a select gate drain selector, a select gate source selector, or some other type of selector. In some examples, a connection between the bit line structures 270 and the plug 253 may be referred to as a selector (e.g., a source side selector, among other examples) and may include a first portion. Each bit line structure 270 may include a first string including a first selector with a first portion and a second string including a second selector with a second portion, where the first and second selectors are coupled to the plug 253.

FIG. 2H illustrates an example of a memory architecture 200-h after a fourth processing step associated with metallization and backside source formation. The memory architecture 200-h illustrates cross-sectional views along the A-A′ and B-B′ cross-sectional lines as described with reference to FIGS. 2E and 2F.

As part of the fourth processing step, a metallization process may be performed to convert the sacrificial material 202 to the metal material 204. The stack of materials may thereby include layers of the oxide material 203 and layers of the metal material 204. The metallization may not alter the structure of the first protective liner 245, the second protective liner 240, the storage material 290, the plug 253, the conductive material 250, or the channel oxide material 255. The plug 253 may have a thickness 254.

The fourth processing step may further include a backside source formation process, in which the source 260 is formed. In some examples, a substrate may be positioned beneath the memory architecture 200-f illustrated in FIG. 2F. As part of the backside source formation, the apparatus may be flipped or otherwise rotated and the substrate may be removed such that the manufacturing system may access a “backside” of the apparatus, which may correspond to a bottom of the first level 210 of the stack of materials 205.

A source material may be deposited from the backside of the apparatus to form the source 260. The source material may include an n+ poly-silicon material, some other material, or any combination thereof. The source material deposition may, in some examples, result in phosphorous diffusion, which may degrade a portion of the plug 253 (e.g., in the vertical or z-direction), but may not degrade or otherwise remove all of the plug 253 due to the plug 253 having sufficient thickness 254. As such, the plug 253 may remain during the backside source formation and the source 260 may be in contact with the plug 253 across the entire or most of the thickness 254 (e.g., over a full surface of the plug 253). The source 260 may thereby be formed without any materials entering the second cavity 235 or other unintended areas of the apparatus. Because the plug 253 extends along the y-direction, even in regions of the apparatus where the bit line structures were removed due to etching, the entire structure is protected from the backside source diffusion, including those areas that do not include bit line structures. For example, as illustrated in the B-B′ cross-sectional view of the memory architecture 200-h, the second cavity 235 may not include any of the source material after the formation of the source 260 because the plug 253 may stop the diffusion of the source material elsewhere in the structure.

The layers of metal material 204 may be word lines configured to access memory cells 105-c, 105-d, and 105-e within the respective layer. For example, a memory cell 105 may be formed at each junction of the storage material 290 with a respective layer of the metal material 204 and a respective bit line structure including the conductive material 250. The memory cells 105-c, 105-d, and 105-e illustrated in FIG. 2H may be included in a memory cell pillar, in some examples. The memory cell pillars may be referred to as strings, in some examples (e.g., multiple memory cells 105 connected in series). Although not illustrated, it is to be understood that three more memory cells 105 may be included in the other side of the A-A′ cross-sectional view of the memory architecture 200-h.

A given memory cell 105 may be accessed by activation of both a corresponding word line and a corresponding bit line structure at the same time. The activation of the word lines (e.g., the metal material 204) may be controlled via one or more word line decoders or other circuitry, which may be positioned under the array (e.g., within a substrate or elsewhere in the memory architecture 200-g). The activation of the bit line structures may be controlled via a transistor or other selection circuitry, which may include the plug 253, the source 260, and the selector 265. For example, a voltage may be applied via the source 260, and the voltage that passes through to the plug 253 and corresponding bit line structures may be controlled by the selector 265 (e.g., a gate at least partially surrounding the plug 253, an electrode). The voltage may be referred to as a threshold voltage, in some examples. The selector 265 may be relatively close to the source 260 (e.g., closer than the other layers of the metal material 204 to the n+ diffusion point), which may provide for more accurate and reliable control of the threshold voltage (e.g., a gate-source voltage) and corresponding current through the conductive material 250 than if the selector 265 is positioned a further distance from the source 260. In some examples, the bit line structures 270 may represent examples of string lines, and one or more bit lines may extend in the y-direction above the stack of materials 205. The one or more bit lines may be coupled with the bit line structures 270 via one or more other selectors.

In some examples, the sharp corners of the various materials within the connection region 256 between the plug 253 and the bit line structures may increase resistance within a memory channel. For example, a resistance of the bit lines may be increased due to the sharp corners, which may decrease string current overall, thereby reducing reliability and performance of the apparatus, in some examples.

Techniques described herein provide for a plug structure that protects against backside source diffusion while maintaining rounded or otherwise curved connection segments and materials within the memory channel to reduce resistance and improve string current, among other benefits.

FIG. 2I illustrates an example of a memory architecture 200-i after the fourth processing step described herein. The memory architecture 200-i illustrates the memory architecture 200-h from a trimetric viewpoint. That is, a portion of the architecture in the y-direction is further shown in FIG. 2I to further illustrate the bit line structures 270 (e.g., bit line structures 270-c, 270-d, and 270-e) and the spacing between them in more detail than shown in the previous figures.

The source 260 may be formed across a bottom of the structure and may be in contact with a surface of the plug 253 in the x- and y-directions. The selector 265 may include the metal material 204 and may extend along the x- and y-directions around the plug 253. That is, the first protective liner 245, the second protective liner 240, and the storage material 290 may be positioned on each side of the plug 253 between the plug 253 and the selector 265. The protective liners 245 and 240, as well as the storage material 290, may continue to extend vertically through the stack. Multiple memory cells 105 may be formed at junctions of the storage material 290, the word lines (e.g., the layers of the metal material 204) and the bit line structures 270, as described and illustrated in FIG. 2H.

The bit line structures 270 may represent rectangular or curved U-shaped segments that extend from the plug 253. For example, each bit line structure 270 may be in contact with (e.g., coupled with) the plug 253 at a respective base contact region 271. The bit line structure 270 may extend horizontally on each side of the base contact region 271. The bit line structure 270 may extend vertically from the horizontal segments on each side of the base contact region 271 and along sidewalls of the stack of materials including the oxide material 203 and the metal material 204 (e.g., word lines). In some examples, a channel oxide material 255 may be positioned on top of the bit line structures 270. Each bit line structure 270 may be physically separated from (e.g., independent from, not in contact with) each other bit line structure 270. For example, the bit line structure 270-c may not be in direct contact with the bit line structure 270-d or the bit line structure 270-e outside of the base contact regions 271 at which each of the bit line structures 270 contacts the plug 253. In some examples, a region where a bit line structure 270 extends vertically along the second protective liner 240 and corresponding storage material 290 may be referred to as a memory cell pillar, as there may be multiple memory cells 105 stacked in that area (e.g., at each layer of the metal material 204).

As described with reference to FIG. 2H, the selector 265 may be configured to adjust, based on a voltage applied to the selector 265, a current that flows through the plug 253 and corresponding bit line structures 270 from the source 260. The apparatus may thereby select one or more memory cells 105 by activating, using the source 260 and the selector 265, the bit line structures 270-c, 270-d, and 270-e, and activating one or more of the word lines (e.g., the layers of the metal material 204) that are at the same level as the target memory cell(s) 105.

As described with reference to FIG. 2H, the base contact region 271 (e.g., the connection region 256 in FIG. 2H) may include one or more sharp edges or corners in which the conductive material changes direction abruptly when transitioning between the plug 253, the horizontal portion of the bit line structures 270, and the vertical portion of the bit line structures 270. In some examples, the sharp corners of the conductive material within the base contact regions 271 and other regions of the bit line structures 270 may increase resistance within a memory channel. For example, a resistance of the bit lines may be increased due to the sharp corners, which may decrease string current overall, thereby reducing reliability and performance of the apparatus, in some examples.

Techniques described herein provide for a plug structure that protects against backside source diffusion while maintaining rounded or otherwise curved connection segments and materials within the memory channel to reduce resistance and improve string current, among other benefits. For example, by utilizing the plug formation techniques described herein, the connection between the plug 253 and the bit line structures 270 may be formed with one or more rounded or otherwise curved corners to reduce resistance and improve string current through the apparatus.

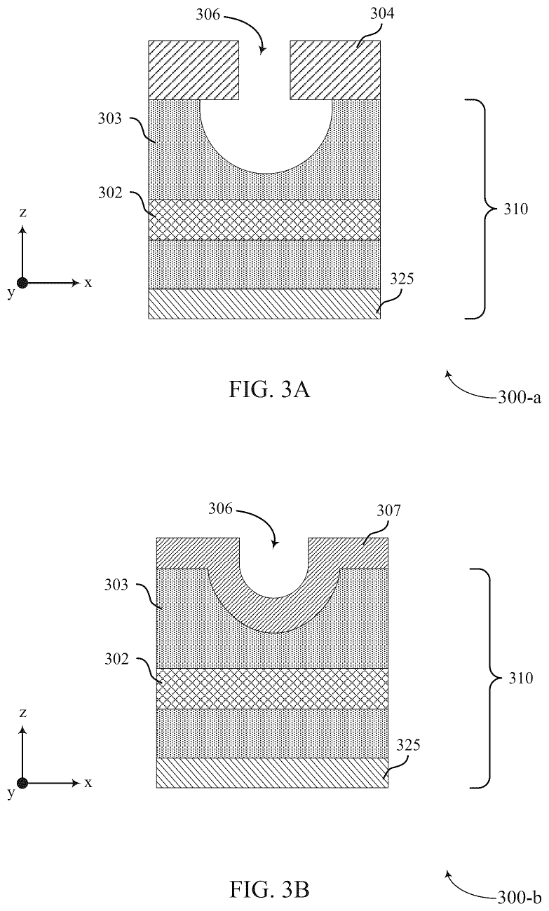

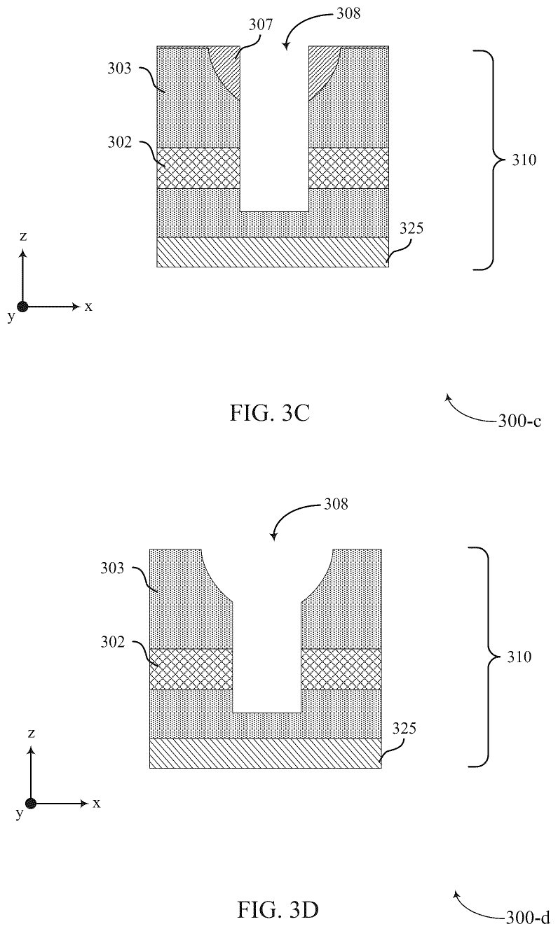

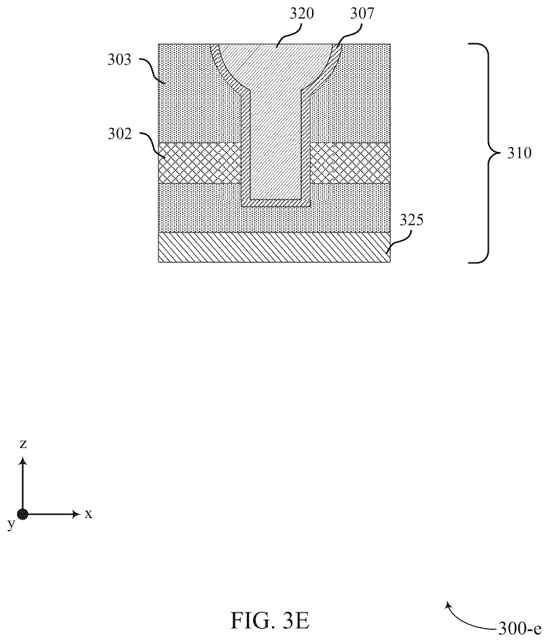

FIGS. 3A through 3E show examples of memory architectures 300 that support formation of a curved plug for protection of backside source formation of vertical planar memory cells in accordance with examples as disclosed herein. The memory architecture 300 may be an example of a portion of an apparatus, such as an apparatus 100. FIGS. 3A through 3E show cross-sectional views of a memory architecture 300, which may be an example of a memory architecture implemented by an apparatus 100, as described with reference to FIGS. 1 and 2. The memory architectures 300 may illustrate operations associated with forming a stack of materials including at least a first level 310 and a sacrificial plug 320, which may represent examples of the first level 210 and the sacrificial plug 220, as described with reference to FIGS. 2A through 2I. However, the sacrificial plug 320 described herein may include one or more curved or otherwise rounded sidewalls to provide for subsequent curved connection between a plug and corresponding bit lines.

The stack of materials may be included in an apparatus including memory cells across one or more levels of the apparatus that are connected with respective bit lines. Performing the processing steps may consolidate processing steps otherwise associated with forming a memory architecture. For example, the processing steps may support reduced diffusion of a source material to unnecessary regions of an apparatus, among other advantages.

For illustrative purposes, aspects of the memory architecture may be described with reference to an x-direction, a y-direction, and a z-direction of the illustrated coordinate systems. For example, memory architectures 300-a, 300-b, 300-c, 300-d, and 300-e illustrate the memory architecture from a cross-sectional and/or planar view, such that a portion of the memory architecture may be removed from a trimetric view to illustrate a cross-section of the memory architecture in the xz-plane. Although the memory architectures 300 illustrate examples of relative dimensions and quantities of various features, aspects of the memory architectures 300 may be implemented with other relative dimensions or quantities of such features in accordance with examples as disclosed herein. In the following description of the processing steps, some methods, techniques, processes, and operations may be performed in different orders or at different times. Further, some operations may be left out of the processing steps, or other operations may be added to the processing steps. Although described as singular processing steps, it is to be understood that each processing step may include one or more multiple processing operations, including, but not limited to, formations, depositions, etches, removals, exhumes, other processing steps, or the like.

Processing steps illustrated in and described with reference to FIGS. 3A through 3E may be performed by a manufacturing system, such as a semiconductor fabrication system configured to perform additive operations such as deposition, formation, bonding, and/or coupling, subtractive operations such as etching, trenching, planarizing, and/or polishing, and supporting operations such as masking, patterning, photolithography, and/or aligning, among other operations that support the described techniques. In some examples, operations performed by such a manufacturing system may be supported by one or more controllers, such as one or more processors or processing circuitry, or its components as described herein.

FIG. 3A illustrates an example of a memory architecture 300-a after a first processing step associated with forming a first level 310 of a stack of materials and a corresponding resistive material 304. For example, forming the stack of materials (e.g., the stack of materials 205 described with reference to FIGS. 2A through 2I) may include depositing alternating (e.g., or at least partially alternating) layers of an oxide material 303 and a sacrificial material 302 above a substrate (e.g., a plane or sheet in the xy-plane on which subsequent memory materials may be formed. The substrate may be associated with complementary metal-oxide semiconductor (CMOS) circuitry. In some such examples, depositing the alternating layers may include depositing a layer of the oxide material 303, then depositing a layer of the sacrificial material 302 above the layer of the oxide material 303. Accordingly, the sacrificial material 302 and the oxide material 303 may be similarly deposited to form alternating layers, where the height of the stack of materials may be based on the quantity and height of each of the alternating layers. In some implementations, the oxide material 303 may be a dielectric material, such as silicon oxide, silicon oxycarbide, silicon oxynitride, or silicon nitride. In some implementations, the sacrificial material 302 may be a variation of nitride.

In some examples, as described with reference to FIG. 2A, the stack of materials may be formed in two or more formation processes. For example, the first level 310 may be formed first, and a second level (e.g., the second level 215 illustrated in FIG. 2A) may be formed after formation of the first level 310. Forming the first level 310 may include depositing one or more layers of an oxide material 303 and one or more layers of the sacrificial material 302 above a substrate. In some examples, the oxide material 303 may be in direct contact with the substrate, or there may be a placeholder material 325 between the substrate and the oxide material 303, as illustrated in FIG. 3A. In the example of FIG. 3A, there may be two layers of the oxide material 303 and a single layer of the sacrificial material 302 in the first level 310. However, it is to be understood that the first level 310 may include any quantity of layers of materials in any alternating order.

After the layers of the first level 310 are formed (e.g., deposited), a resistive material 304 may be formed on top of the first level 310. The resistive material 304 may be a material that resists or withstands one or more types of etching, such as wet etching. The resistive material 304 may be formed using a mask or in accordance with some other patterning technique, such that two segments of the resistive material 304 are formed on top of the first level 310 and there is a gap or space between the two segments in the x-direction. The two segments may each extend, along the top of the stack, in the y-direction (e.g., into the page in FIG. 3A). The gap may generally be centered or near a center of the stack. A size (e.g., width) of the gap between the two segments may be based on one or more parameters associated with the stack and a strength of the etch operation.

After the resistive material 304 is formed, an etch operation may be performed (e.g., a wet etch). The etch operation may etch, via the gap in the resistive material 304, at least a portion of the top layer of the oxide material 303. The etch operation may be applied in such a way so as to create a rounder or otherwise curved cavity 306 within the first layer of the oxide material 303. As illustrated in FIG. 3, the cavity 306 may have a semi-circular shape or a U-shape within the oxide material 303. The etch may not extend to the sacrificial material 302.

FIG. 3B illustrates an example of a memory architecture 300-b after a second processing step associated with removing the resistive material 304 and forming a liner material 307, which may be a silicon oxide (SiO2) material, or some other material.

For example, after the cavity 306 is formed, the resistive material 304 may be removed from the stack of materials. After the resistive material 304 is removed, a liner material 307 may be formed within the cavity 306 and along a top surface of the first level 310. The liner material 307 may be an SiO2 material, or some other type of material. The liner material 307 may be formed with a relatively even thickness across the stack in the x-direction. For example, a thickness of the liner material 307 on a top surface of the first level 310 may be equal to a thickness of the liner material 307 as the material extends around the curved sidewalls of the cavity 306. A portion of the cavity 306 may remain above the liner material 307.

FIG. 3C illustrates an example of a memory architecture 300-c after a third processing step associated with further etching the first level 310 of the stack of materials. For example, after the liner material 307 is formed, a second etch operation may be performed to remove materials from the stack and form a second cavity 308 that extends further into the first level 310 of materials in the z-direction than the cavity 306 in FIGS. 3A and 3B.

The second etch operation may be a dry etch, in some examples (e.g., SiO2 dry etching and polysilicon dry etching). The second etch may remove a portion of the liner material 307, a portion of one or more layers of the oxide material 303, and a portion of the layer of the sacrificial material 302 to form a trench that extends through the first level 310 of the stack of materials in the z-direction and the y-direction (e.g., into the page in FIG. 3C).

In some examples, no liner material 307 may remain on the top surfaces of the first level 310 after the second etch operation. Additionally, or alternatively, all or a relatively thin portion of the liner material 307 may remain on the top surfaces of the stack. A portion of the liner material 307 may remain within the previous cavity 306. For example, a section of the liner material 307 may be removed from a central portion for the cavity 308, but liner material 307 that is lower than a top surface of the stack and includes curved sidewalls may remain after the second etch operation.

In some examples, the second etch operation may be performed using a mask or other patterning technique, such that only an area that is the width of the cavity 308 is etched and other areas of the first level 310 of materials are not etched. The remaining liner material 307 may thereby form a sacrificial or shape-holding purpose.

FIG. 3D illustrates an example of a memory architecture 300-d after a fourth processing step associated with forming a sacrificial plug 320. For example, after the second etch operation is performed to form the second cavity 308, the remaining liner material 307 may be removed from the first level 310 (e.g., via an exhume or other etch process). The removal of the liner material 307 may re-expose the cavity 306 within the cavity 308.

After the liner material 307 is removed, additional liner material 307 may be deposited within the cavity 308 and the cavity 306 (e.g., re-deposited). The additional liner material 307 may be formed with a thickness than is less than the first thickness of the liner material 307 after the first deposition, in some examples. The additional liner material 307 may line sidewalls of the cavity 308 (e.g., a bottom sidewall and two other sidewalls) with the thickness and may line sidewalls of the cavity 306 (e.g., curved sidewalls) with the thickness.

After the additional liner material 307 is formed, a sacrificial plug 220 may be formed within the cavity 308 and the cavity 306. For example, a sacrificial plug material (e.g., tungsten or some other material) may be deposited within the cavity 308 and the cavity 306 to form the sacrificial plug 320. The liner material 307 may extend along each sidewall except a top surface of the sacrificial plug 320 (e.g., between the sacrificial plug 320 and the first level 310 of the stack of materials). The sacrificial plug 320 may be in the shape of a partial keyhole. For example, the sacrificial plug 320 may include a rectangular portion (e.g., a rectangular prism that extends in the y-direction) and a semi-circular portion above the rectangular portion (e.g., a semi-circular prism that extends in the y-direction). A diameter of the semi-circular portion may be greater than a width of the rectangular portion of the sacrificial plug 320 in the x-direction, in some examples.

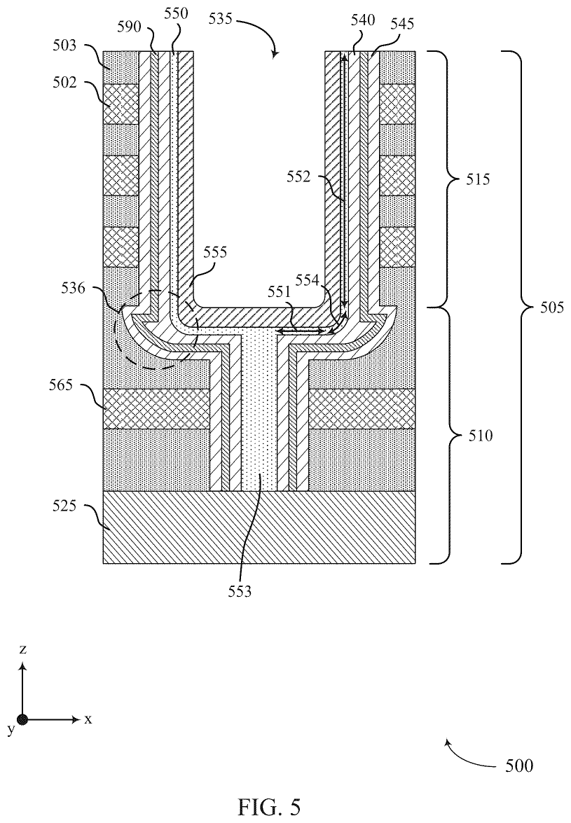

After the sacrificial plug 320 is formed, a second level of the stack of materials may subsequently be formed on top of the first level 310 and the sacrificial plug 320, as described with reference to FIG. 2A. In some examples, the second level may be further formed (e.g., deposited and etched) such that a resulting memory architecture including a plug in contact with access lines is formed, as described in further detail elsewhere herein, including with reference to FIG. 5. The formation of the U-shaped sacrificial plug 320 may provide for formation of curved connections between a plug and access lines, which may improve reliability of the apparatus, as described in further detail elsewhere herein, including with reference to FIG. 5.

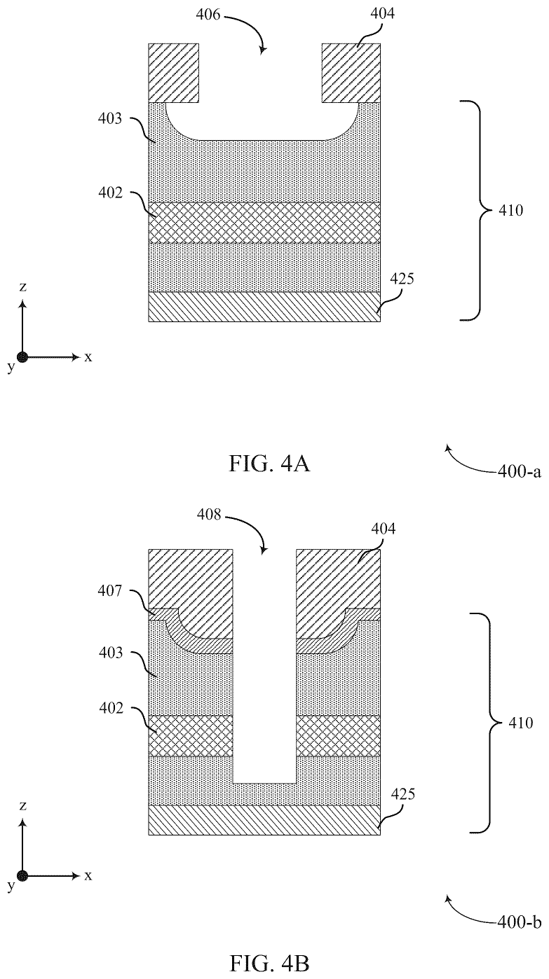

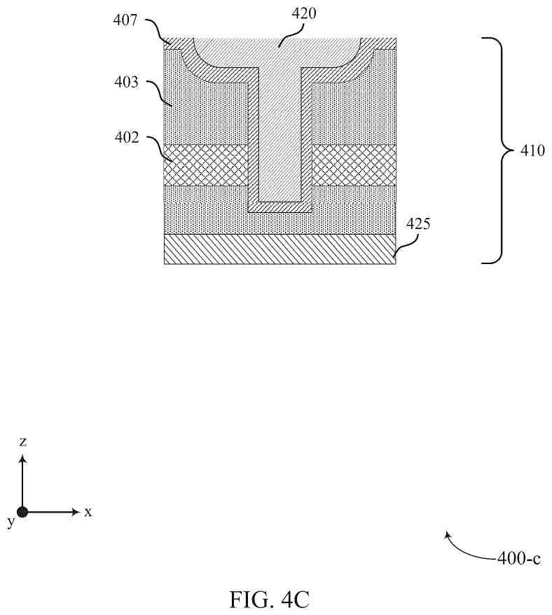

FIGS. 4A through 4C show examples of memory architectures 400 that support formation of a curved plug for protection of backside source formation of vertical planar memory cells in accordance with examples as disclosed herein. The memory architecture 400 may be an example of a portion of an apparatus, such as an apparatus 100. FIGS. 4A through 4C show cross-sectional views of a memory architecture 400, which may be an example of a memory architecture implemented by an apparatus 100, as described with reference to FIGS. 1 through 3E. The memory architectures 400 may illustrate operations associated with forming a stack of materials including at least a first level 410 and a sacrificial plug 420, which may represent examples of the first level 210 and the sacrificial plug 220 or the first level 310 and the sacrificial plug 320, as described with reference to FIGS. 2A through 3E. However, the sacrificial plug 420 described herein may include one or more curved or otherwise rounded sidewalls to provide for subsequent curved connection between a plug and corresponding bit lines.

The stack of materials may be included in an apparatus including memory cells across one or more levels of the apparatus that are connected with respective bit lines. Performing the processing steps may consolidate processing steps otherwise associated with forming a memory architecture. For example, the processing steps may support reduced diffusion of a source material to unnecessary regions of the apparatus, among other advantages.

For illustrative purposes, aspects of the memory architecture may be described with reference to an x-direction, a y-direction, and a z-direction of the illustrated coordinate systems. For example, memory architectures 400-a, 400-b, and 400-c illustrate the memory architecture from a cross-sectional and/or planar view, such that a portion of the memory architecture may be removed from a trimetric view to illustrate a cross-section of the memory architecture in the xz-plane. Although the memory architectures 400 illustrate examples of relative dimensions and quantities of various features, aspects of the memory architectures 400 may be implemented with other relative dimensions or quantities of such features in accordance with examples as disclosed herein. In the following description of the processing steps, some methods, techniques, processes, and operations may be performed in different orders or at different times. Further, some operations may be left out of the processing steps, or other operations may be added to the processing steps. Although described as singular processing steps, it is to be understood that each processing step may include one or more multiple processing operations, including, but not limited to, formations, depositions, etches, removals, exhumes, other processing steps, or the like.

Operations illustrated in and described with reference to FIGS. 4A through 4C may be performed by a manufacturing system, such as a semiconductor fabrication system configured to perform additive operations such as deposition, formation, bonding, and/or coupling, subtractive operations such as etching, trenching, planarizing, and/or polishing, and supporting operations such as masking, patterning, photolithography, and/or aligning, among other operations that support the described techniques. In some examples, operations performed by such a manufacturing system may be supported by one or more controllers, such as one or more processors or processing circuitry, or its components as described herein.

FIG. 4A illustrates an example of a memory architecture 400-a after a first processing step associated with forming a first level 410 of a stack of materials and a corresponding resistive material 404. For example, forming the stack of materials (e.g., the stack of materials 205 described with reference to FIGS. 2A through 2I) may include depositing alternating (e.g., or at least partially alternating) layers of an oxide material 403 and a sacrificial material 402 above a substrate (e.g., a plane or sheet in the xy-plane on which subsequent memory materials may be formed. The substrate may be associated with complementary metal-oxide semiconductor (CMOS) circuitry. In some such examples, depositing the alternating layers may include depositing a layer of the oxide material 403, then depositing a layer of the sacrificial material 402 above the layer of the oxide material 403. Accordingly, the sacrificial material 402 and the oxide material 403 may be similarly deposited to form alternating layers, where the height of the stack of materials may be based on the quantity and height of each of the alternating layers. In some implementations, the oxide material 403 may be a dielectric material, such as silicon oxide, silicon oxycarbide, silicon oxynitride, or silicon nitride. In some implementations, the sacrificial material 402 may be a variation of nitride.

In some examples, as described with reference to FIG. 2A, the stack of materials may be formed in two or more formation processes. For example, the first level 410 may be formed first, and a second level (e.g., the second level 215 illustrated in FIG. 2A) may be formed after formation of the first level 410. Forming the first level 410 may include depositing one or more layers of an oxide material 403 and one or more layers of the sacrificial material 402 above a substrate. In some examples, the oxide material 403 may be in direct contact with the substrate, or there may be a placeholder material 425 between the substrate and the oxide material 403, as illustrated in FIG. 4A. In the example of FIG. 4A, there may be two layers of the oxide material 403 and a single layer of the sacrificial material 402 in the first level 410. However, it is to be understood that the first level 410 may include any quantity of layers of materials in any alternating order.

After the layers of the first level 410 are formed (e.g., deposited), a resistive material 404 may be formed on top of the first level 410. The resistive material 404 may be a material that resists or withstands one or more types of etching, such as wet etching. The resistive material 404 may be formed using a mask or in accordance with some other patterning technique, such that two segments of the resistive material 404 are formed on top of the first level 410 and there is a gap or space between the two segments in the x-direction. The two segments may each extend, along the top of the stack, in the y-direction (e.g., into the page in FIG. 4A). The gap may generally be centered or near a center of the stack. A size (e.g., width) of the gap between the two segments may be based on one or more parameters associated with the stack and a strength of the etch operation. In this example, the size of the gap between the two segments of resistive material 404 may be greater than the gap illustrated in FIG. 3A, which may result in a different shape of a resulting cavity 406.

After the resistive material 404 is formed, an etch operation may be performed (e.g., a wet etch). The etch operation may etch, via the gap in the resistive material 404, at least a portion of the top layer of the oxide material 403. The etch operation may be applied in such a way so as to create a rounder or otherwise curved cavity 406 within the first layer of the oxide material 403. The cavity 406 may have a straight bottom sidewall with two curves on each side, as illustrated. The straight sidewall may be formed by even etching of the oxide material 403 within the gap region between the two segments of the resistive material 404. The curved sidewalls may be formed based on etching applied underneath the resistive material 404. As illustrated in FIG. 4A, the cavity 406 may have a U-shape within the oxide material 403. The etch may not extend to the sacrificial material 402.

FIG. 4B illustrates an example of a memory architecture 400-b after a second processing step associated with removing the resistive material 404, forming a liner material 407, and further etching the first level 410. For example, after the cavity 406 is formed, the resistive material 404 may be removed from the stack of materials. After the resistive material 404 is removed, a liner material 407 may be formed within the cavity 406 and along a top surface of the first level 410. The liner material 407 may be an SiO2 material, or some other type of material. The liner material 407 may be formed with a relatively even thickness across the stack in the x-direction (e.g., via SiO2 deposition and lithography). For example, a thickness of the liner material 407 on a top surface of the first level 410 may be equal to a thickness of the liner material 407 as the material extends along the bottom sidewall and around the curved sidewalls of the cavity 406.

After the liner material 407 is formed, resistive material 404 may be re-formed. For example, a layer of the resistive material 404 may be formed above the liner material 407. In some examples, the layer of the resistive material 404 may extend across the first level 410 in the x-direction and may have a planar top surface.

After the resistive material 404 is re-formed, a second etch operation may be performed to remove materials from the stack and form a second cavity 408 that extends further into the first level 410 of materials in the z-direction than the cavity 406 in FIG. 4A.

The second etch operation may be a dry etch, in some examples (e.g., SiO2 dry etching and polysilicon dry etching). The second etch may remove a portion of the resistive material 404, a portion of the liner material 407, a portion of one or more layers of the oxide material 403, and a portion of the layer of the sacrificial material 402 to form a trench that extends through the first level 410 of the stack of materials in the z-direction and the y-direction (e.g., into the page in FIG. 4B).

Remaining portions of the liner material 407 may remain with the shape of at least a portion of the previous cavity 406. For example, the remaining liner material 407 after the second etch operation may include curved sidewalls.

In some examples, the second etch operation may be performed using a mask or other patterning technique, such that only an area that is the width of the cavity 408 is etched and other areas of the first level 410 of materials are not etched. The remaining liner material 407 may thereby form a sacrificial or shape-holding purpose.

FIG. 4C illustrates an example of a memory architecture 400-c after a third processing step associated with forming a sacrificial plug 420. For example, after the second etch operation is performed to form the second cavity 408, the remaining liner material 407 and resistive material 404 may be removed from the first level 410 (e.g., via an exhume or other etch process). The removal of the liner material 407 and the resistive material 404 may re-expose the cavity 406 within the cavity 408.

After the liner material 407 and the resistive material 404 are removed, additional liner material 407 may be deposited within the cavity 408 and the cavity 406 (e.g., re-deposited). The additional liner material 407 may be formed with a thickness than is the same as or less than the first thickness of the liner material 407 after the first deposition, in some examples. The additional liner material 407 may line sidewalls of the cavity 408 (e.g., a bottom sidewall and two other sidewalls) with the thickness and may line sidewalls of the cavity 406 (e.g., curved sidewalls) with the thickness.

After the additional liner material 407 is formed, a sacrificial plug 420 may be formed within the cavity 408 and the cavity 406. For example, a sacrificial plug material (e.g., tungsten or some other material) may be deposited within the cavity 408 and the cavity 406 to form the sacrificial plug 420. The liner material 407 may extend along each sidewall except a top surface of the sacrificial plug 420 (e.g., between the sacrificial plug 420 and the first level 410 of the stack of materials). The sacrificial plug 420 may include a rectangular portion (e.g., a rectangular prism that extends in the y-direction) and a U-shaped portion above the rectangular portion (e.g., a bowl or plate shape with a straight bottom portion and curved sidewalls that extends in the y-direction). A diameter of the U-shaped portion may be greater than a width of the rectangular portion of the sacrificial plug 420 in the x-direction, in some examples.

After the sacrificial plug 420 is formed, a second level of the stack of materials may subsequently be formed on top of the first level 410 and the sacrificial plug 420, as described with reference to FIG. 2A. In some examples, the second level may be further formed (e.g., deposited and etched) such that a resulting memory architecture including a plug in contact with access lines is formed, as described in further detail elsewhere herein, including with reference to FIG. 5. The formation of the U-shaped sacrificial plug 420 may provide for formation of curved connections between a plug and access lines, which may improve reliability of the apparatus, as described in further detail elsewhere herein, including with reference to FIG. 5.

FIG. 5 shows an example of a memory architecture 500 that supports formation of a curved plug for protection of backside source formation of vertical planar memory cells in accordance with examples as disclosed herein. The memory architecture 500 may be an example of a portion of an apparatus, such as an apparatus 100. FIG. 5 shows a cross-sectional view of a memory architecture 500, which may be an example of a memory architecture implemented by an apparatus 100, as described with reference to FIGS. 1 through 4C. The memory architecture 500 may illustrate an architecture of a portion of an apparatus after one or more processing steps associated with forming a stack of materials 505 including at least a first level 510 and a second level 515. The first level 510 may be formed in accordance with the processing steps described with reference to FIGS. 3A through 3E or in accordance with the processing steps described with reference to FIGS. 4A through 4C.

The stack of materials 505 may be included in an apparatus including memory cells across one or more levels of the apparatus that are connected with respective bit lines. Performing the processing steps may consolidate processing steps otherwise associated with forming a memory architecture. For example, the processing steps may support reduced diffusion of a source material to unnecessary regions of an apparatus, among other advantages.

For illustrative purposes, aspects of the memory architecture 500 may be described with reference to an x-direction, a y-direction, and a z-direction of the illustrated coordinate systems. For example, the memory architecture 500 illustrates the memory architecture from a cross-sectional and/or planar view, such that a portion of the memory architecture may be removed from a trimetric view to illustrate a cross-section of the memory architecture in the xz-plane. Although the memory architecture 500 illustrates examples of relative dimensions and quantities of various features, aspects of the memory architecture 500 may be implemented with other relative dimensions or quantities of such features in accordance with examples as disclosed herein. In the following description of the processing steps, some methods, techniques, processes, and operations may be performed in different orders or at different times. Further, some operations may be left out of the processing steps, or other operations may be added to the processing steps. Although described as singular processing steps, it is to be understood that each processing step may include one or more multiple processing operations, including, but not limited to, formations, depositions, etches, removals, exhumes, other processing steps, or the like.

Processing steps illustrated in and described with reference to FIG. 5 may be performed by a manufacturing system, such as a semiconductor fabrication system configured to perform additive operations such as deposition, formation, bonding, and/or coupling, subtractive operations such as etching, trenching, planarizing, and/or polishing, and supporting operations such as masking, patterning, photolithography, and/or aligning, among other operations that support the described techniques. In some examples, operations performed by such a manufacturing system may be supported by one or more controllers, such as one or more processors or processing circuitry, or its components as described herein.

As described with reference to FIGS. 3A through 3E and FIGS. 4A through 4C, a sacrificial plug may be formed in the first level 510 of the stack of materials 505. The sacrificial plug may be in the shape of the sacrificial plug 320 illustrated in FIG. 3E or the sacrificial plug 420 illustrated in FIG. 4C, or some other shape with at least partially curved sidewalls. After the sacrificial plug and the first level 510 are formed, the second level 515 may be formed. For example, one or more layers of the oxide material 503 and the sacrificial material 502 may be deposited in an alternating pattern on top of the first level 510 and the sacrificial plug. In some examples, a top layer of the first level 510 may include the oxide material 503 and a bottom layer of the second level 515 may include the oxide material, as illustrated. Additionally, or alternatively, the materials may be formed in any order.

After the second level 515 of the stack of materials 505 is formed, a cavity 535 may be formed through the second level 515. The cavity 535 may represent an example of the cavity 235 described with reference to FIG. 2A. For example, the cavity 535 may be formed through the second level 515 to the sacrificial plug. The sacrificial plug material may subsequently be removed (e.g., exhumed, etched) via the cavity 535, which may result in a second cavity, similar to the cavity 237 described with reference to FIGS. 2A through 2I, in the first level 510 of the stack of materials 505, and a recessed region 536 between the first cavity and the second cavity. A shape of the recessed region 536 may be the same as a shape of the sacrificial plug (e.g., as illustrated in FIG. 3E, FIG. 4C, or some other shape). For example, at least one sidewall of the recessed region 536 may be curved instead of straight. In the example of FIG. 5, the recessed region 536 may be similar in shape to a quarter of a circle.

As described with reference to FIGS. 2C through 2F, one or more other materials may be deposited within the cavities and the recessed region 536 formed from removal of the sacrificial plug. The layers of materials that may be formed may include, for example, a first protective liner 545, a storage material 590, and a second protective liner 540, each of which may represent examples of corresponding materials as described with reference to FIGS. 2A through 2I. In this example, however, the material liners may be formed along sidewalls of the stack of materials 505 having the curved recessed region 536. As such, the material liners may have at least one segment that is curved. The first protective liner 545 and the storage material 590 may, in some examples, be formed with one or more corners within the recessed region 536. For example, the first protective liner 545 and the storage material 590 may curve along a sidewall of the stack of materials 505 in the recessed region 536 and may turn, with a sharp corner, to a horizontal segment, before turning at another corner to a vertical segment that ultimately extends up the second level 515 of the stack of materials 505. The second protective liner 540 may be formed with uneven thickness in the recessed region 536, such that an outer surface of the second protective liner 540 is smooth and curved with no corners or sharp angles. That is, the outer surface of the second protective liner 540 may be a U-shape or other curved or rounded shape. The second protective liner 540 may thereby fill the recessed region 536.

After the first protective liner 545, the storage material 590, and the second protective liner 540 are formed, a conductive material 550 may be formed. The conductive material 550 may be formed over the second protective liner 540 within a remainder of the cavities. The conductive material 550 may fill any remaining space within the cavity that previously included the sacrificial plug, in some examples. The conductive material 550 within the first level 510 may be referred to as a conductive plug 553, in some examples described herein, and may provide protection from source diffusion as described herein. For example, the conductive plug 553 may represent a rectangular prism of conductive material 550 extending in the y-direction and the z-direction through the first level 510 of the stack of materials 505.

The conductive material 550 may further be formed as a liner or channel that extends from the conductive plug 553 through the second level 515 of the stack of materials 505. The conductive material 550 that extends from the conductive plug may be associated with (e.g., may include or otherwise form) one or more bit lines of the apparatus. The one or more bit lines may each include at least a first segment 551 that extends in a horizontal direction (e.g., the x-direction) from the conductive plug 553, a second segment 552 that extends vertically (e.g., in the z-direction) through the second level 515, and a connection segment 554 that includes a curved shape and curves between the first segment 551 and the second segment 552. The described techniques thereby provide for the connection segment 554 between the conductive plug 553 and the one or more bit lines to be curved. For example, due to the formation of the curved sacrificial plugs described with reference to FIGS. 3A through 4C, and the further formation of the protective liners and storage material 590 to fill the recessed region 536, the conductive material 550 may be formed along a smooth curved surface, which may reduce resistance and improve string current through the conductive material 550 (e.g., the bit lines) during operation of the apparatus.

In some examples, a channel oxide material 555 may be formed on top of the conductive material 550 within the second level 515. The channel oxide material 555 may be formed on top of the conductive material 550 and may be formed with a threshold thickness or may be etched back, such that the channel oxide material 555 has a relatively constant thickness within the cavity 535. In some examples, the formation of the channel oxide material 555 may reduce a thickness of the conductive material 550 within the second cavity 535, as illustrated in FIG. 5. The cavity 535 (e.g., a trench) may represent an absence of material extending between the conductive material on each side of the stack of materials 505.

The techniques described herein may thereby provide for formation of the conductive plug 553 connected to bit line structures via a curved connection segment 554. Details of the formation of and shape of the various materials within the memory architecture 500 are illustrated and described in further detail elsewhere herein, including with reference to FIGS. 2A through 2I. For example, a metallization process may subsequently be performed, as well as a backside source formation operation. The metallization process may convert the sacrificial material 502 to conductive material (e.g., word lines). The backside source formation operation may generate a source in replacement of the placeholder material 525, where the source may extend into a portion of the plug 553 but may not enter other regions of the device based on the plug 553 providing protection between the memory cell stacks. the memory architecture 500 may be extended in each of the three dimensions similar to the memory architecture 200-i as described with reference to and illustrated in FIG. 2I but may include curves in the bit line structures instead of sharp corners.

The curve in the connection segment 554 may improve electric field in the connection region as compared with a pointy or sharp corner in the connection region, as illustrated in FIG. 2H, thereby reducing a threshold voltage. Additionally, or alternatively, the curves may reduce resistance within the bit line structures. For example, a voltage may be applied to the plug 553 via the selector 565. The applied voltage may activate a current via the plug 553 (e.g., from the source) and through the bit line structures. The current may flow via the first segment 551, the second segment 552, and the connection segment 554 to activate memory cells coupled with the bit lines. The curve within the connection segment 554 may thereby increase gate induced drain leakage as compared to plug structures with corners or other protruding regions, improving current and reliability of memory access operations, among other techniques as described herein.

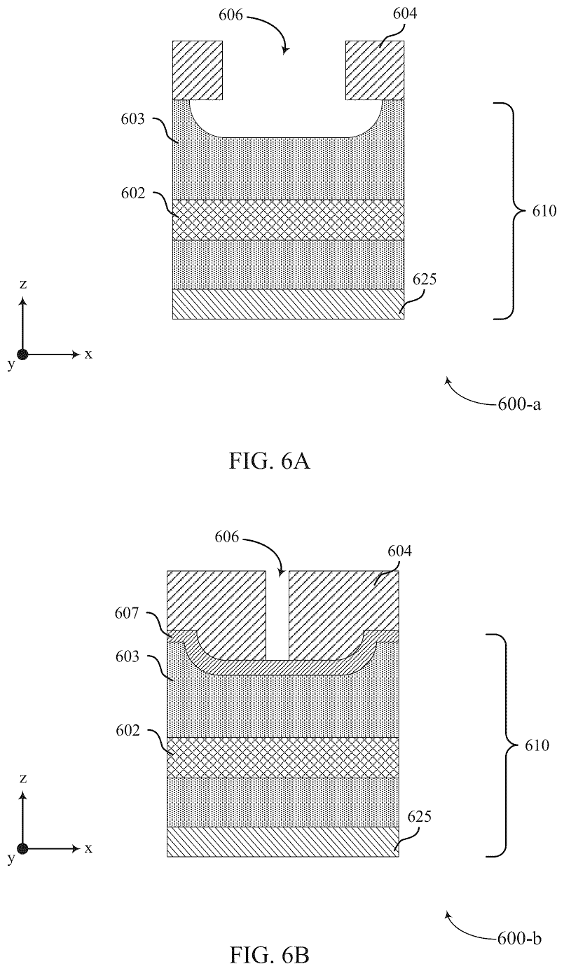

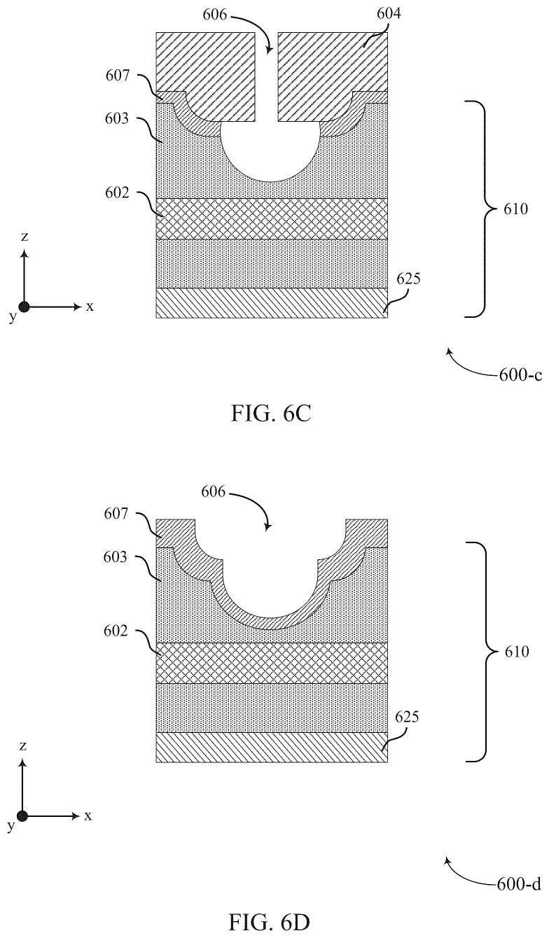

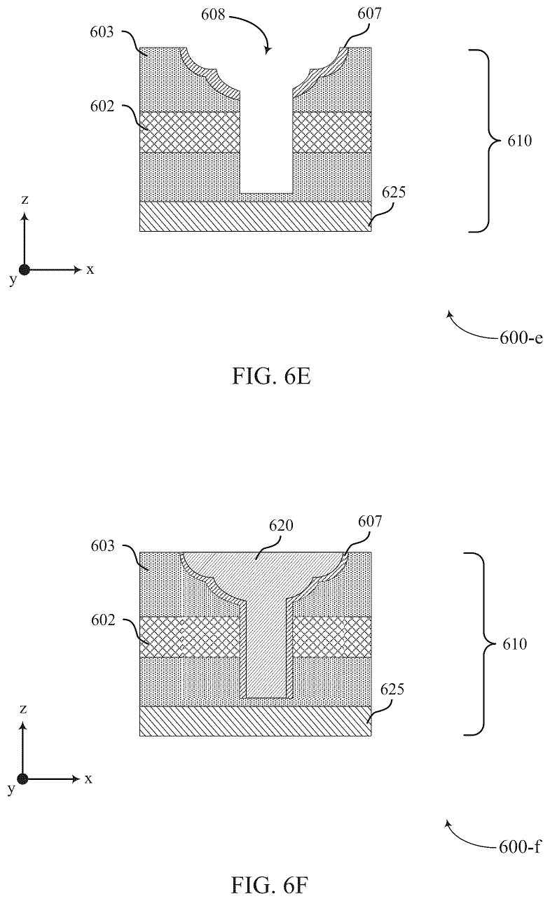

FIGS. 6A through 6F show examples of memory architectures 600 that support formation of a curved plug for protection of backside source formation of vertical planar memory cells in accordance with examples as disclosed herein. The memory architecture 600 may be an example of a portion of an apparatus, such as an apparatus 100. FIGS. 6A through 6F show cross-sectional views of a memory architecture 600, which may be an example of a memory architecture implemented by an apparatus 100, as described with reference to FIGS. 1 through 5. The memory architectures 600 may illustrate operations associated with forming a stack of materials including at least a first level 610 and a sacrificial plug 620, which may represent examples of the first level 210 and the sacrificial plug 220, as described with reference to FIGS. 2A through 2I. However, the sacrificial plug 620 described herein may include one or more curved or otherwise rounded sidewalls to provide for subsequent curved connection between a plug and corresponding bit lines. In this example, techniques for forming a double U-shaped sacrificial plug 620 are described (e.g., a plug with more than one curved portion).

The stack of materials may be included in an apparatus including memory cells across one or more levels of the apparatus that are connected with respective bit lines. Performing the processing steps may consolidate processing steps otherwise associated with forming a memory architecture. For example, the processing steps may support reduced diffusion of a source material to unnecessary regions of an apparatus, among other advantages.

For illustrative purposes, aspects of the memory architecture may be described with reference to an x-direction, a y-direction, and a z-direction of the illustrated coordinate systems. For example, memory architectures 600-a, 600-b, 600-c, 600-d, 600-e, and 600-f illustrate the memory architecture from a cross-sectional and/or planar view, such that a portion of the memory architecture may be removed from a trimetric view to illustrate a cross-section of the memory architecture in the xz-plane. Although the memory architectures 600 illustrate examples of relative dimensions and quantities of various features, aspects of the memory architectures 600 may be implemented with other relative dimensions or quantities of such features in accordance with examples as disclosed herein. In the following description of the processing steps, some methods, techniques, processes, and operations may be performed in different orders or at different times. Further, some operations may be left out of the processing steps, or other operations may be added to the processing steps. Although described as singular processing steps, it is to be understood that each processing step may include one or more multiple processing operations, including, but not limited to, formations, depositions, etches, removals, exhumes, other processing steps, or the like.

Operations illustrated in and described with reference to FIGS. 6A through 6F may be performed by a manufacturing system, such as a semiconductor fabrication system configured to perform additive operations such as deposition, formation, bonding, and/or coupling, subtractive operations such as etching, trenching, planarizing, and/or polishing, and supporting operations such as masking, patterning, photolithography, and/or aligning, among other operations that support the described techniques. In some examples, operations performed by such a manufacturing system may be supported by one or more controllers, such as one or more processors or processing circuitry, or its components as described herein.

FIG. 6A illustrates an example of a memory architecture 600-a after a first processing step associated with forming a first level 610 of a stack of materials and a corresponding resistive material 604. For example, forming the stack of materials (e.g., the stack of materials 205 described with reference to FIGS. 2A through 2I) may include depositing alternating (e.g., or at least partially alternating) layers of an oxide material 603 and a sacrificial material 602 above a substrate (e.g., a plane or sheet in the xy-plane on which subsequent memory materials may be formed. The substrate may be associated with CMOS circuitry. In some such examples, depositing the alternating layers may include depositing a layer of the oxide material 603, then depositing a layer of the sacrificial material 602 above the layer of the oxide material 603. Accordingly, the sacrificial material 602 and the oxide material 603 may be similarly deposited to form alternating layers, where the height of the stack of materials may be based on the quantity and height of each of the alternating layers. In some implementations, the oxide material 603 may be a dielectric material, such as silicon oxide, silicon oxycarbide, silicon oxynitride, or silicon nitride. In some implementations, the sacrificial material 602 may be a variation of nitride.

In some examples, as described with reference to FIG. 2A, the stack of materials may be formed in two or more formation processes. For example, the first level 610 may be formed first, and a second level (e.g., the second level 215 illustrated in FIG. 2A) may be formed after formation of the first level 610. Forming the first level 610 may include depositing one or more layers of an oxide material 603 and one or more layers of the sacrificial material 602 above a substrate. In some examples, the oxide material 603 may be in direct contact with the substrate, or there may be a placeholder material 625 between the substrate and the oxide material 603, as illustrated in FIG. 6A. In the example of FIG. 6A, there may be two layers of the oxide material 603 and a single layer of the sacrificial material 602 in the first level 610. However, it is to be understood that the first level 610 may include any quantity of layers of materials in any alternating order.

After the layers of the first level 610 are formed (e.g., deposited), a resistive material 604 may be formed on top of the first level 610. The resistive material 604 may be a material that resists or withstands one or more types of etching, such as wet etching. The resistive material 604 may be formed using a mask or in accordance with some other patterning technique, such that two segments of the resistive material 604 are formed on top of the first level 610 and there is a gap or space between the two segments in the x-direction. The two segments may each extend, along the top of the stack, in the y-direction (e.g., into the page in FIG. 6A). The gap may generally be centered or near a center of the stack. A size (e.g., width) of the gap between the two segments may be based on one or more parameters associated with the stack and a strength of the etch operation.

After the resistive material 604 is formed, an etch operation may be performed (e.g., a wet etch). The etch operation may etch, via the gap in the resistive material 604, at least a portion of the top layer of the oxide material 603. The etch operation may be applied in such a way so as to create a rounder or otherwise curved cavity 606 within the first layer of the oxide material 603. As illustrated in FIG. 6A, The cavity 606 may have a straight bottom sidewall with two curves on each side, as illustrated. The straight sidewall may be formed by even etching of the oxide material 603 within the gap region between the two segments of the resistive material 604. The curved sidewalls may be formed based on etching applied underneath the resistive material 604. The etch may not extend to the sacrificial material 602.

FIG. 6B illustrates an example of a memory architecture 600-b after a second processing step associated with removing the resistive material 604 and forming a liner material 607, which may be a silicon oxide (SiO2) material, or some other material.

For example, after the cavity 606 is formed, the resistive material 604 may be removed from the stack of materials. After the resistive material 604 is removed, a liner material 607 may be formed within the cavity 606 and along a top surface of the first level 610. The liner material 607 may be an SiO2 material, or some other type of material. The liner material 607 may be formed with a relatively even thickness across the stack in the x-direction. For example, a thickness of the liner material 607 on a top surface of the first level 610 may be equal to a thickness of the liner material 607 as the material extends around the curved sidewalls and the straight bottom sidewall of the cavity 606. A portion of the cavity 606 may remain above the liner material 607.

After the liner material 607 is formed, more of the resistive material 604 may be formed (e.g., re-deposited). For example, the resistive material 604 may be formed using a mask or in accordance with some other patterning technique, such that two segments of the resistive material 604 are formed on top of the liner material 607 and there is a gap or space between the two segments in the x-direction. The two segments may each extend, along the top of the stack, in the y-direction (e.g., into the page in FIG. 6B). The gap may generally be centered or near a center of the stack. A size (e.g., width) of the gap between the two segments may be based on one or more parameters associated with the stack and a strength of the etch operation. This gap may be relatively narrow (e.g., smaller than the gap illustrated in FIG. 6A).

FIG. 6C illustrates an example of a memory architecture 600-c after a third processing step associated with further etching the first level 610 of the stack of materials. For example, after the liner material 607 and the second round of resistive material 604 are formed, a second etch operation may be performed to further expand a size and shape of the cavity 606.

After the second resistive material 604 is formed, an etch operation may be performed (e.g., a wet etch). The etch operation may etch, via the gap in the resistive material 604, at least a further portion of the top layer of the oxide material 603. The etch operation may be applied in such a way so as to create an additional round or otherwise curved portion in the cavity 606 within the first layer of the oxide material 603. As illustrated in FIG. 6A, The additional portion of the cavity 606 may be a circular shape, in some examples. For example, the cavity 606 may extend as a semi-circle or arc within a portion of the first layer of the oxide material 603. The cavity 606 may extend in the y-direction (e.g., into the page in FIG. 6C). The etch may not extend to the sacrificial material 602.

The rounded shape of the cavity 606 as formed by the second etch may be based on the size and shape of the gap between the two segments of the resistive material 604. For example, because the gap is narrower than the gap illustrated in FIG. 6A, the wet etch may be applied with a tapered effect in the oxide material 603. That is, an amount of material that is removed may be tapered from a center of the gap, which may produce the rounded cavity 606.

FIG. 6D illustrates an example of a memory architecture 600-d after a fourth processing step associated with removing the resistive material 604 and re-forming the liner material 607. For example, after the second etch operation, the resistive material 604 may be removed from the stack (e.g., exhumed, etched). After the removal of the resistive material 604, the liner material 607 may be removed or otherwise re-formed. For example, the liner material 607 may be removed and additional liner material 607 may be formed in the top surfaces of the stack as exposed by the cavity 606. Additionally, or alternatively, the liner material 607 in FIG. 6C may remain, and additional liner material 607 may be deposited.

The resulting liner material 607 may line the three curved surfaces within the cavity 606. The liner material 607 may have a same thickness across the surfaces or may vary in thickness as the liner material 607 extends in the y-direction. In some examples, if the additional liner material 607 is deposited, a resulting liner may have a greater thickness at regions where the liner material 607 was already present (e.g., as in FIG. 6C).

The cavity 606 may be similar in shape to a portion of an outline of three circles in a triangular formation. For example, the top surface of the cavity 606 may start, in the x-direction, with a concave curvature that curves (e.g., in a backwards J-shape) to a point, then curves again along another convex curvature having a semi-circular or U shape, to a second point, at which the surface further curves along a convex curvature having a J-shape, to a top surface of the first level 610.

FIG. 6E illustrates an example of a memory architecture 600-e after a fifth processing step associated with a third etch process to further materials from the stack and form a second cavity 608 that extends further into the first level 610 of materials in the z-direction than the cavity 606 in FIGS. 6A through 6D.

The third etch operation may be a dry etch, in some examples (e.g., SiO2 dry etching and polysilicon dry etching). The third etch may remove a portion of the liner material 607, a portion of one or more layers of the oxide material 603, and a portion of the layer of the sacrificial material 602 to form a trench that extends through the first level 610 of the stack of materials in the z-direction and the y-direction (e.g., into the page in FIG. 6E).

In some examples, no liner material 607 may remain on the top surfaces of the first level 610 (e.g., external to the cavity 606) after the third etch operation. Additionally, or alternatively, all or a relatively thin portion of the liner material 607 may remain on the top surfaces of the stack. A portion of the liner material 607 may remain within the previous cavity 606. For example, a section of the liner material 607 may be removed from a central portion for the cavity 608, but liner material 607 that is lower than a top surface of the stack and includes curved sidewalls may remain after the third etch operation.

In some examples, the third etch operation may be performed using a mask or other patterning technique, such that only an area that is the width of the cavity 608 is etched and other areas of the first level 610 of materials are not etched. The remaining liner material 607 may thereby form a sacrificial or shape-holding purpose.

FIG. 6F illustrates an example of a memory architecture 600-d after a sixth processing step associated with forming a sacrificial plug 620. For example, after the third etch operation is performed to form the second cavity 608, the remaining liner material 607 may be removed from the first level 610 (e.g., via an exhume or other etch process). The removal of the liner material 607 may re-expose the cavity 606 within the cavity 608.

After the liner material 607 is removed, additional liner material 607 may be deposited within the cavity 608 and the cavity 606 (e.g., re-deposited). The additional liner material 607 may be formed with a thickness than is less than the first thickness of the liner material 607 after the first deposition, in some examples. The additional liner material 607 may line sidewalls of the cavity 608 (e.g., a bottom sidewall and/or two other sidewalls) with the thickness and may line sidewalls of the cavity 606 (e.g., curved sidewalls) with the thickness.

After the additional liner material 607 is formed, a sacrificial plug 620 may be formed within the cavity 608 and the cavity 606. For example, a sacrificial plug material (e.g., tungsten or some other material) may be deposited within the cavity 608 and the cavity 606 to form the sacrificial plug 620. The liner material 607 may extend along each sidewall except a top surface of the sacrificial plug 620 (e.g., between the sacrificial plug 620 and the first level 610 of the stack of materials) and, in some examples may not extend on a bottom surface of the sacrificial plug 620. The sacrificial plug 620 may include a rectangular portion (e.g., a rectangular prism that extends in the y-direction) and a semi-circular portion above the rectangular portion (e.g., a semi-circular prism that extends in the y-direction), along with another curved region above the semi-circular portion to form a double U-shaped prism that extends in the y-direction. A diameter or width of the rounded portions above the layer of sacrificial material 602 may be greater than a width of the rectangular portion of the sacrificial plug 620 in the x-direction, in some examples.

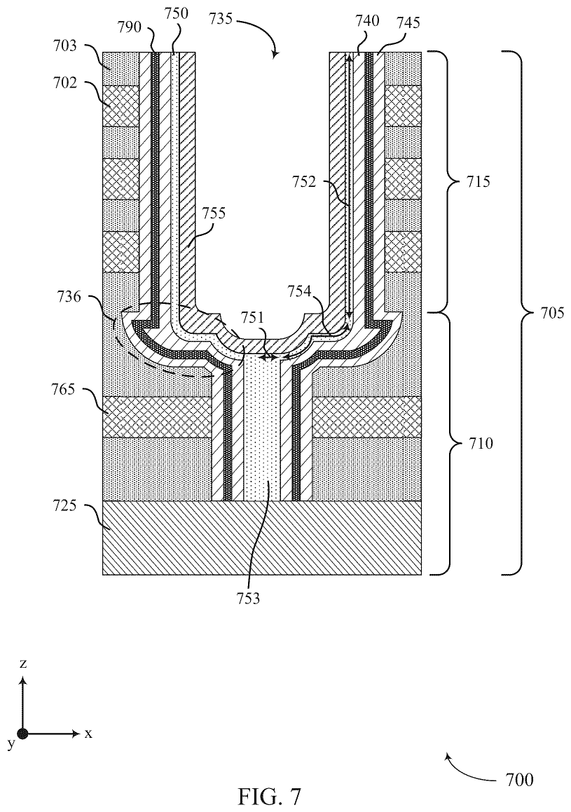

After the sacrificial plug 620 is formed, a second level of the stack of materials may subsequently be formed on top of the first level 610 and the sacrificial plug 620, as described with reference to FIG. 2A. In some examples, the second level may be further formed (e.g., deposited and etched) such that a resulting memory architecture including a plug in contact with access lines is formed, as described in further detail elsewhere herein, including with reference to FIG. 7. The formation of the U-shaped sacrificial plug 620 may provide for formation of curved connections between a plug and access lines, which may improve reliability of the apparatus, as described in further detail elsewhere herein, including with reference to FIG. 7.

FIG. 7 shows an example of a memory architecture 700 that supports formation of a curved plug for protection of backside source formation of vertical planar memory cells in accordance with examples as disclosed herein. The memory architecture 700 may be an example of a portion of an apparatus (e.g., a memory system), such as an apparatus 100. FIG. 7 shows a cross-sectional view of a memory architecture 700, which may be an example of a memory architecture implemented by an apparatus 100, as described with reference to FIGS. 1 through 6F. The memory architecture 700 may illustrate an architecture of a portion of an apparatus after one or more processing steps associated with forming a stack of materials 705 including at least a first level 710 and a second level 715. The first level 710 may be formed in accordance with the processing steps described with reference to FIGS. 6A through 6F.

The stack of materials 705 may be included in an apparatus including memory cells across one or more levels of the apparatus that are connected with respective bit lines. Performing the processing steps may consolidate processing steps otherwise associated with forming a memory architecture. For example, the processing steps may support reduced diffusion of a source material to unnecessary regions of an apparatus, among other advantages.

For illustrative purposes, aspects of the memory architecture 700 may be described with reference to an x-direction, a y-direction, and a z-direction of the illustrated coordinate systems. For example, the memory architecture 700 illustrates the memory architecture from a cross-sectional and/or planar view, such that a portion of the memory architecture may be removed from a trimetric view to illustrate a cross-section of the memory architecture in the xz-plane. Although the memory architecture 700 illustrates examples of relative dimensions and quantities of various features, aspects of the memory architecture 700 may be implemented with other relative dimensions or quantities of such features in accordance with examples as disclosed herein. In the following description of the processing steps, some methods, techniques, processes, and operations may be performed in different orders or at different times. Further, some operations may be left out of the processing steps, or other operations may be added to the processing steps. Although described as singular processing steps, it is to be understood that each processing step may include one or more multiple processing operations, including, but not limited to, formations, depositions, etches, removals, exhumes, other processing steps, or the like.

Operations illustrated in and described with reference to FIG. 7 may be performed by a manufacturing system, such as a semiconductor fabrication system configured to perform additive operations such as deposition, formation, bonding, and/or coupling, subtractive operations such as etching, trenching, planarizing, and/or polishing, and supporting operations such as masking, patterning, photolithography, and/or aligning, among other operations that support the described techniques. In some examples, operations performed by such a manufacturing system may be supported by one or more controllers, such as one or more processors or processing circuitry, or its components as described herein.

As described with reference to FIGS. 6A through 6F, a sacrificial plug may be formed in the first level 710 of the stack of materials 705. The sacrificial plug may be in the shape of the sacrificial plug 620 illustrated in FIG. 6F, or some other shape with at least two partially curved sidewalls (e.g., a double U-shape). After the sacrificial plug and the first level 710 are formed, the second level 715 may be formed. For example, one or more layers of the oxide material 703 and the sacrificial material 702 may be deposited in an alternating pattern on top of the first level 710 and the sacrificial plug. In some examples, a top layer of the first level 710 may include the oxide material 703 and a bottom layer of the second level 715 may include the oxide material, as illustrated. Additionally, or alternatively, the materials may be formed in any order.

After the second level 715 of the stack of materials 705 is formed, a cavity 735 may be formed through the second level 715. The cavity 735 may represent an example of the cavity 235 described with reference to FIG. 2A. For example, the cavity 735 may be formed through the second level 715 to the sacrificial plug. The sacrificial plug material may subsequently be removed (e.g., exhumed, etched) via the cavity 735, which may result in a second cavity, similar to the cavity 237 described with reference to FIGS. 2A through 2I, in the first level 710 of the stack of materials 705, and a recessed region 736 between the first cavity and the second cavity. A shape of the recessed region 736 may be the same as a shape of a top portion of the sacrificial plug (e.g., as illustrated in FIG. 6F, or some other shape). For example, the recessed region 736 may include at least two curved sidewalls instead of a straight sidewall. In the example of FIG. 7, the recessed region 736 may be similar in shape two quarter circles, or two concave arcs connected together.

As described with reference to FIGS. 2C through 2F, one or more other materials may be deposited within the cavities and the recessed region 736 formed from removal of the sacrificial plug. The layers of materials that may be formed may include, for example, a first protective liner 745, a storage material 790, and a second protective liner 740, each of which may represent examples of corresponding materials as described with reference to FIGS. 2A through 2I. In this example, however, the material liners may be formed along sidewalls of the stack of materials 705 having the curved recessed region 736. As such, the material liners may have at least two segments that are curved. The first protective liner 745 and the storage material 790 may, in some examples, be formed with one or more corners within the recessed region 736. For example, the first protective liner 745 and the storage material 790 may curve along a first sidewall of the stack of materials 705 in the recessed region 736 and may turn, at a pointed corner, to curve alone a second sidewall of the stack of materials 705. The first protective liner 745 and the storage material 790 may then turn, with a sharp corner, to a horizontal segment, before turning at another corner to a vertical segment that ultimately extends up the second level 715 of the stack of materials 705. The second protective liner 740 may be formed with uneven thickness in the recessed region 736, such that an outer surface of the second protective liner 740 (e.g., facing toward the cavity 735) is smooth and curved with no corners or sharp angles. That is, the outer surface of the second protective liner 740 may be a double U-shape or other curved or rounded shape with two concave curves. The second protective liner 740 may thereby fill the recessed region 736.

After the first protective liner 745, the storage material 790, and the second protective liner 740 are formed, a conductive material 750 may be formed. The conductive material 750 may be formed over the second protective liner 740 within a remainder of the cavities. The conductive material 750 may fill any remaining space within the cavity that previously included the sacrificial plug, in some examples. The conductive material 750 within the first level 710 may be referred to as a conductive plug 753, in some examples described herein, and may provide protection from source diffusion as described herein. For example, the conductive plug 753 may represent a rectangular prism of conductive material 750 extending in the y-direction and the z-direction through the first level 710 of the stack of materials 705.

The conductive material 750 may further be formed as a liner or channel that extends from the conductive plug 753 through the second level 715 of the stack of materials 705. The conductive material 750 that extends from the conductive plug 753 may be associated with (e.g., may include or otherwise form) one or more bit line structures of the apparatus. The one or more bit lines may each include at least a first segment 751 that extends in a horizontal direction (e.g., the x-direction) from the conductive plug 753, a second segment 752 that extends vertically (e.g., in the z-direction) through the second level 715, and a connection segment 754 that includes at least two curvatures (e.g., a double U-shape or two C-shapes connected together) and curves between the first segment 751 and the second segment 752. The described techniques thereby provide for the connection segment 754 between the conductive plug 753 and the one or more bit lines to be curved. For example, due to the formation of the curved sacrificial plugs described with reference to FIGS. 6A through 6F, and the further formation of the protective liners and storage material 790 to fill the recessed region 736, the conductive material 750 may be formed along a smooth, twice-curved surface, which may reduce resistance and improve string current through the conductive material 750 (e.g., the bit lines) during operation of the apparatus.

In some examples, a channel oxide material 755 may be formed on top of the conductive material 750 within the second level 715. The channel oxide material 755 may be formed on top of the conductive material 750 and may be formed with a threshold thickness or may be etched back, such that the channel oxide material 755 has a relatively constant thickness within the cavity 735. In some examples, the formation of the channel oxide material 755 may reduce a thickness of the conductive material 750 within the second cavity 735, as illustrated in FIG. 7. The cavity 735 (e.g., a trench) may represent an absence of material extending between the conductive material on each side of the stack of materials 705.

The techniques described herein may thereby provide for formation of the conductive plug 753 connected to bit line structures via a twice-curved connection segment 754. Details of the formation of and shape of the various materials within the memory architecture 700 are illustrated and described in further detail elsewhere herein, including with reference to FIGS. 2A through 2I. For example, a metallization process may subsequently be performed, as well as a backside source formation operation. The metallization process may convert the sacrificial material 702 to conductive material (e.g., word lines). The backside source formation operation may generate a source in replacement of the placeholder material 725, where the source may extend into a portion of the plug 753 but may not enter other regions of the device based on the plug 753 providing protection between the memory cell stacks. the memory architecture 700 may be extended in each of the three dimensions similar to the memory architecture 200-i as described with reference to and illustrated in FIG. 2I but may include curves in the bit line structures instead of sharp corners.

The curves in the connection segment 754 may improve electric field in the connection region as compared with a pointy or sharp corner in the connection region, as illustrated in FIG. 2H, thereby reducing a threshold voltage. Additionally, or alternatively, the curves may reduce resistance within the bit line structures. For example, a voltage may be applied to the plug 753 via the selector 765. The applied voltage may activate a current via the plug 753 (e.g., from the source) and through the bit line structures. The current may flow via the first segment 751, the second segment 752, and the connection segment 754 to activate memory cells coupled with the bit lines. The curves within the connection segment 754 may thereby increase gate induced drain leakage as compared to plug structures with corners or other protruding regions, improving current and reliability of memory access operations, among other techniques as described herein.

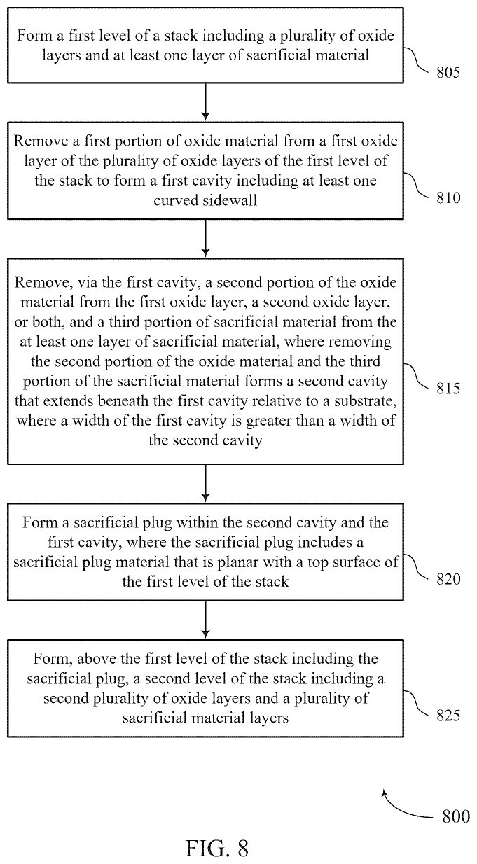

FIG. 8 shows a flowchart illustrating a method 800 that supports curved plug for protection of backside source formation of vertical planar memory cells in accordance with examples as disclosed herein. The operations of method 800 may be implemented by a manufacturing system or its components as described herein. For example, the operations of method 800 may be performed by a manufacturing system as described with reference to FIGS. 1 through 7. In some examples, a manufacturing system may execute a set of instructions to control the functional elements of the device to perform the described functions. Additionally, or alternatively, the manufacturing system may perform aspects of the described functions using special-purpose hardware.

At 805, the method may include forming a first level of a stack including a plurality of oxide layers and at least one layer of sacrificial material.

At 810, the method may include removing a first portion of oxide material from a first oxide layer of the plurality of oxide layers of the first level of the stack to form a first cavity including at least one curved sidewall.

At 815, the method may include removing, via the first cavity, a second portion of the oxide material from the first oxide layer, a second oxide layer, or both, and a third portion of sacrificial material from the at least one layer of sacrificial material, where removing the second portion of the oxide material and the third portion of the sacrificial material forms a second cavity that extends beneath the first cavity relative to a substrate, where a width of the first cavity is greater than a width of the second cavity.

At 820, the method may include forming a sacrificial plug within the second cavity and the first cavity, where the sacrificial plug includes a sacrificial plug material that is planar with a top surface of the first level of the stack.

At 825, the method may include forming, above the first level of the stack including the sacrificial plug, a second level of the stack including a second plurality of oxide layers and a plurality of sacrificial material layers.

In some examples, an apparatus as described herein may perform a method or methods, such as the method 800. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for forming a first level of a stack including a plurality of oxide layers and at least one layer of sacrificial material; removing a first portion of oxide material from a first oxide layer of the plurality of oxide layers of the first level of the stack to form a first cavity including at least one curved sidewall; removing, via the first cavity, a second portion of the oxide material from the first oxide layer, a second oxide layer, or both, and a third portion of sacrificial material from the at least one layer of sacrificial material, where removing the second portion of the oxide material and the third portion of the sacrificial material forms a second cavity that extends beneath the first cavity relative to a substrate, where a width of the first cavity is greater than a width of the second cavity; forming a sacrificial plug within the second cavity and the first cavity, where the sacrificial plug includes a sacrificial plug material that is planar with a top surface of the first level of the stack; and forming, above the first level of the stack including the sacrificial plug, a second level of the stack including a second plurality of oxide layers and a plurality of sacrificial material layers.

Aspect 2: The method, apparatus, or non-transitory computer-readable medium of aspect 1, further including operations, features, circuitry, logic, means, or instructions, or any combination thereof for forming a third cavity that extends through the second level of the stack in a first direction; removing, via the third cavity, the sacrificial plug material to re-form the first cavity and the second cavity, the first cavity including the at least one curved sidewall; and forming layers of materials within the first cavity, the second cavity, and the third cavity, the materials including a protective liner, a storage material, and a second protective liner.

Aspect 3: The method, apparatus, or non-transitory computer-readable medium of aspect 2, further including operations, features, circuitry, logic, means, or instructions, or any combination thereof for forming, after forming the layers of materials, a conductive material within the first cavity and the second cavity, where the conductive material forms a plug within the second cavity and etching the conductive material in the second level of the stack to form a plurality of bit line structures that extend from the plug through the second level of the stack, where each bit line structure of the plurality of bit line structures is at least partially curved based at least in part on the at least one curved sidewall of the first cavity, and where each bit line structure of the plurality of bit line structures is physically isolated from other bit line structures within the second level of the stack based at least in part on the etching.

Aspect 4: The method, apparatus, or non-transitory computer-readable medium of any of aspects 1 through 3, where the first cavity includes a semi-cylindrical cavity within the first oxide layer of the plurality of oxide layers.

Aspect 5: The method, apparatus, or non-transitory computer-readable medium of any of aspects 1 through 3, where the first cavity includes at least one straight sidewall and two curved sidewalls a U-shape within the first oxide layer of the plurality of oxide layers.

Aspect 6: The method, apparatus, or non-transitory computer-readable medium of aspect 5, further including operations, features, circuitry, logic, means, or instructions, or any combination thereof for depositing a resistive material within the first cavity after removing the first portion of the oxide material; removing, via an etching operation based at least in part on the resistive material, a fourth portion of the oxide material from the first oxide layer to expand a size of the first cavity; and removing, after removing the fourth portion of the oxide material, the resistive material from the stack, where removing the second portion of the oxide material and the third portion of the sacrificial material is based at least in part on removing the fourth portion of the oxide material and the resistive material from the stack.

Aspect 7: The method, apparatus, or non-transitory computer-readable medium of any of aspects 1 through 3, where the first cavity includes a first U-shaped sidewall and two second curved sidewalls within the first oxide layer of the plurality of oxide layers.

It should be noted that the described methods include possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 8: An apparatus, including: a substrate; a stack including a plurality of oxide layers and a plurality of metal layers, the stack including a first level positioned between the substrate and a second level in a first direction; a plug passing through the first level of the stack in the first direction and including a conductive material; a plurality of bit line structures extending from the plug through the second level of the stack, where each bit line structure of the plurality of bit line structures is coupled with the plug within a respective contact region and is physically isolated from other bit line structures of the plurality of bit line structures within other regions different from the respective contact region, and where each bit line structure of the plurality of bit line structures includes: a first segment that extends from the plug in a second direction within the stack; a second segment that extends in the first direction through the second level of the stack; and a connection segment including a curved shape that connects the first segment to the second segment; and a plurality of memory cells positioned in the second level of the stack, each memory cell of the plurality of memory cells positioned between a respective metal layer of the plurality of metal layers and a respective first segment of each bit line structure of the plurality of bit line structures.

Aspect 9: The apparatus of aspect 8, further including: a storage material liner that extends between the plug and the first level of the stack, where each memory cell of the plurality of memory cells includes a respective portion of the storage material liner, and where the storage material liner further includes: a third segment that extends in the first direction between first segments of the plurality of bit line structures and the second level of the stack; and a second connection segment including at least one curved shape that connects the third segment to the storage material liner in the first level of the stack.

Aspect 10: The apparatus of any of aspects 8 through 9, where the plurality of bit line structures includes: a first subset of bit line structures on a first side of the plug in the second direction, where respective first segments of the first subset of bit line structures are dispersed along a first axis in a third direction; and a second subset of bit line structures on a second side of the plug in the second direction, where respective first segments of the second subset of bit line structures are dispersed along a second axis in the third direction.

Aspect 11: The apparatus of any of aspects 8 through 10, further including: a plurality of liners that extend between the plug and the first level of the stack in the first direction and that extend between first segments of the plurality of bit line structures and the second level of the stack in the first direction, where the plurality of liners further curve between the plurality of bit line structures and the stack within a connection region between the plug and the first segments, and where the plurality of liners include at least a storage material liner and a protective liner.

Aspect 12: The apparatus of any of aspects 8 through 11, further including: a plurality of separation regions between the plurality of bit line structures within the second level, where each pair of adjacent bit line structures is physically isolated from each other by a respective separation region of the plurality of separation regions, and where each separation region of the plurality of separation regions includes a separation material that extends between a respective pair of adjacent bit line structures in the first direction.

Aspect 13: The apparatus of aspect 12, further including: a storage material liner that extends between the plug and the stack in the first level where: the storage material liner is positioned between the plurality of bit line structures and the stack in the second level; the separation material is positioned between the storage material liner and the stack within the plurality of separation regions in the second level; and the storage material liner extends in a third direction between each bit line structure of the plurality of bit line structures and an adjacent separation region of the plurality of separation regions.

Aspect 14: The apparatus of any of aspects 12 through 13, where in each separation region of the plurality of separation regions, a storage material liner is positioned between the plug in the first level of the stack and the separation material in the second level of the stack.

Aspect 15: The apparatus of any of aspects 8 through 14, where the plug includes a pillar of oxide material, the conductive material in contact with at least two sidewalls of the pillar of oxide material.

Aspect 16: The apparatus of any of aspects 8 through 15, further including: a plurality of oxide liners that each extend along a top surface of a respective bit line structure of the plurality of bit line structures, each oxide liner of the plurality of oxide liners including at least one curved segment associated with a respective connection segment of a corresponding bit line structure of the plurality of bit line structures.

Aspect 17: The apparatus of any of aspects 8 through 16, where the first level of the stack includes: a first selector within a first metal layer of the plurality of metal layers, the first selector configured to apply a voltage to the plurality of bit line structures via the plug.

Aspect 18: The apparatus of aspect 17, where the first level of the stack includes: the first metal layer of the plurality of metal layers positioned between two oxide layers of the plurality of oxide layers in the first direction.

Aspect 19: The apparatus of any of aspects 8 through 16, where the first level of the stack includes: a first oxide layer of the plurality of oxide layers, where the plurality of metal layers are within the second level of the stack.

An apparatus is described. The following provides an overview of aspects of the apparatus as described herein:

Aspect 20: An apparatus, including: a substrate; a stack including a plurality of oxide layers and a plurality of metal layers, the stack including a first level and a second level, the first level positioned between the substrate and the second level in a first direction; a plug passing through the first level of the stack, where the plug extends, in the first direction, along a first axis, the plug including a conductive material; a plurality of bit line structures extending from the plug through the second level of the stack, where each bit line structure of the plurality of bit line structures is coupled with the plug within a respective contact region and is physically isolated from other bit line structures of the plurality of bit line structures within other regions different from the respective contact region, and where each bit line structure of the plurality of bit line structures includes: a first segment that extends, in the first direction, along a second axis through the second level of the stack, the second axis offset from the first axis in a second direction different from the first direction; a second segment that curves away from the plug in the first direction and the second direction; and a third segment that curves between the second segment and the first segment, where the third segment is in contact with the first segment and the second segment; and a plurality of memory cells positioned in the second level of the stack, each memory cell of the plurality of memory cells positioned between a respective memory layer of the plurality of metal layers and a respective first segment of each bit line structure of the plurality of bit line structures.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials, or combinations thereof. In some examples, one layer or level may be composed of two or more sublayers or sublevels.

As used herein, the term “electrode” may refer to an electrical conductor, and in some examples, may be employed as an electrical contact to a memory cell or other component of a memory array. An electrode may include a trace, wire, conductive line, conductive layer, or the like that provides a conductive path between elements or components of a memory array.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed and second condition or action may occur directly as a result of the previous condition or action occurring independent of whether other conditions or actions occur. In some examples, a first condition or action may be performed and second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a substrate;
a stack comprising a plurality of oxide layers and a plurality of metal layers, the stack comprising a first level positioned between the substrate and a second level in a first direction;
a plug passing through the first level of the stack in the first direction and comprising a conductive material;
a plurality of bit line structures extending from the plug through the second level of the stack, wherein each bit line structure of the plurality of bit line structures comprises:
a first segment that extends from the plug in a second direction within the stack;
a second segment that extends in the first direction through the second level of the stack; and
a connection segment comprising a curved shape that connects the first segment to the second segment; and
a plurality of memory cells positioned in the second level of the stack, each memory cell of the plurality of memory cells positioned between a respective metal layer of the plurality of metal layers and a respective first segment of each bit line structure of the plurality of bit line structures.

2. The apparatus of claim 1, wherein each bit line structure of the plurality of bit line structures is coupled with the plug within a respective contact region and is physically isolated from other bit line structures of the plurality of bit line structures within other regions different from the respective contact region.

3. The apparatus of claim 1, further comprising:
a storage material liner that extends between the plug and the first level of the stack, where each memory cell of the plurality of memory cells comprises a respective portion of the storage material liner, and wherein the storage material liner further comprises:
a third segment that extends in the first direction between first segments of the plurality of bit line structures and the second level of the stack; and
a second connection segment comprising at least one curved shape that connects the third segment to the storage material liner in the first level of the stack.

4. The apparatus of claim 1, wherein the plurality of bit line structures comprises:
a first subset of bit line structures on a first side of the plug in the second direction, wherein respective first segments of the first subset of bit line structures are dispersed along a first axis in a third direction; and
a second subset of bit line structures on a second side of the plug in the second direction, wherein respective first segments of the second subset of bit line structures are dispersed along a second axis in the third direction.

5. The apparatus of claim 1, further comprising:
a plurality of liners that extend between the plug and the first level of the stack in the first direction and that extend between first segments of the plurality of bit line structures and the second level of the stack in the first direction, wherein the plurality of liners further curves between the plurality of bit line structures and the stack within a connection region between the plug and the first segments, and wherein the plurality of liners comprise at least a storage material liner and a protective liner.

6. The apparatus of claim 1, further comprising:
a plurality of separation regions between the plurality of bit line structures within the second level, wherein each pair of adjacent bit line structures is physically isolated from each other by a respective separation region of the plurality of separation regions, and wherein each separation region of the plurality of separation regions comprises a separation material that extends between a respective pair of adjacent bit line structures in the first direction.

7. The apparatus of claim 6, further comprising:
a storage material liner that extends between the plug and the stack in the first level wherein:
the storage material liner is positioned between the plurality of bit line structures and the stack in the second level;
the separation material is positioned between the storage material liner and the stack within the plurality of separation regions in the second level; and
the storage material liner extends in a third direction between each bit line structure of the plurality of bit line structures and an adjacent separation region of the plurality of separation regions.

8. The apparatus of claim 6, wherein in each separation region of the plurality of separation regions, a storage material liner is positioned between the plug in the first level of the stack and the separation material in the second level of the stack.

9. The apparatus of claim 1, wherein the plug comprises a pillar of oxide material, the conductive material in contact with at least two sidewalls of the pillar of oxide material.

10. The apparatus of claim 1, further comprising:
a plurality of oxide liners that each extend along a top surface of a respective bit line structure of the plurality of bit line structures, each oxide liner of the plurality of oxide liners comprising at least one curved segment associated with a respective connection segment of a corresponding bit line structure of the plurality of bit line structures.

11. The apparatus of claim 1, wherein the first level of the stack comprises:
a first selector within a first metal layer of the plurality of metal layers, the first selector configured to apply a voltage to the plurality of bit line structures via the plug.

12. The apparatus of claim 11, wherein the first level of the stack comprises:
the first metal layer of the plurality of metal layers positioned between two oxide layers of the plurality of oxide layers in the first direction.

13. The apparatus of claim 1, wherein the first level of the stack comprises:
a first oxide layer of the plurality of oxide layers, wherein the plurality of metal layers are within the second level of the stack.

14. A method, comprising:
forming a first level of a stack comprising a plurality of oxide layers and at least one layer of sacrificial material;
removing a first portion of oxide material from a first oxide layer of the plurality of oxide layers of the first level of the stack to form a first cavity comprising at least one curved sidewall;
removing, via the first cavity, a second portion of the oxide material from the first oxide layer, a second oxide layer, or both, and a third portion of sacrificial material from the at least one layer of sacrificial material, wherein removing the second portion of the oxide material and the third portion of the sacrificial material forms a second cavity that extends beneath the first cavity relative to a substrate, wherein a width of the first cavity is greater than a width of the second cavity;
forming a sacrificial plug within the second cavity and the first cavity, wherein the sacrificial plug comprises a sacrificial plug material that is planar with a top surface of the first level of the stack; and
forming, above the first level of the stack comprising the sacrificial plug, a second level of the stack comprising a second plurality of oxide layers and a plurality of sacrificial material layers.

15. The method of claim 14, further comprising:
forming a third cavity that extends through the second level of the stack in a first direction;
removing, via the third cavity, the sacrificial plug material to re-form the first cavity and the second cavity, the first cavity comprising the at least one curved sidewall; and
forming layers of materials within the first cavity, the second cavity, and the third cavity, the materials comprising a protective liner, a storage material, and a second protective liner.

16. The method of claim 15, further comprising:
forming, after forming the layers of materials, a conductive material within the first cavity and the second cavity, wherein the conductive material forms a plug within the second cavity; and
etching the conductive material in the second level of the stack to form a plurality of bit line structures that extend from the plug through the second level of the stack, wherein each bit line structure of the plurality of bit line structures is at least partially curved based at least in part on the at least one curved sidewall of the first cavity, and wherein each bit line structure of the plurality of bit line structures is physically isolated from other bit line structures within the second level of the stack based at least in part on etching the conductive material in the second level of the stack.

17. The method of claim 14, wherein the first cavity comprises a semi-cylindrical cavity within the first oxide layer of the plurality of oxide layers.

18. The method of claim 14, wherein the first cavity comprises at least one straight sidewall and two curved sidewalls a U-shape within the first oxide layer of the plurality of oxide layers.

19. The method of claim 18, further comprising:
depositing a resistive material within the first cavity after removing the first portion of the oxide material;
removing, via an etching operation based at least in part on the resistive material, a fourth portion of the oxide material from the first oxide layer to expand a size of the first cavity; and
removing, after removing the fourth portion of the oxide material, the resistive material from the stack, wherein removing the second portion of the oxide material and the third portion of the sacrificial material is based at least in part on removing the fourth portion of the oxide material and the resistive material from the stack.

20. The method of claim 14, wherein the first cavity comprises a first U-shaped sidewall and two second curved sidewalls within the first oxide layer of the plurality of oxide layers.

21. An apparatus, comprising:
a substrate;
a stack comprising a plurality of oxide layers and a plurality of metal layers, the stack comprising a first level and a second level, the first level positioned between the substrate and the second level in a first direction;
a plug passing through the first level of the stack, wherein the plug extends, in the first direction, along a first axis, the plug comprising a conductive material;
a plurality of bit line structures extending from the plug through the second level of the stack, wherein each bit line structure of the plurality of bit line structures is coupled with the plug within a respective contact region and is physically isolated from other bit line structures of the plurality of bit line structures within other regions different from the respective contact region, and wherein each bit line structure of the plurality of bit line structures comprises:
a first segment that extends, in the first direction, along a second axis through the second level of the stack, the second axis offset from the first axis in a second direction different from the first direction;
a second segment that curves away from the plug in the first direction and the second direction; and
a third segment that curves between the second segment and the first segment, wherein the third segment is in contact with the first segment and the second segment; and
a plurality of memory cells positioned in the second level of the stack, each memory cell of the plurality of memory cells positioned between a respective memory layer of the plurality of metal layers and a respective first segment of each bit line structure of the plurality of bit line structures.
